(19) United States
(12) Patent Application Publication
(10) Pub. No.: US 2006/0057287 A1
(43) Pub. Date: Mar. 16, 2006

(54) Method of making chemical vapor composites

(75) Inventors: Colby Foss, Kapaa, HI (US); Clifford Tanaka, Lihue, HI (US); Nathan Wood, Kapaa, HI (US); William Fischer, Kapaa, HI (US); David Kane, Lihue, HI (US); Bruce MacDonald, Arlington, VA (US); Tesse Tanigawa, Kapaa, HI (US); David N. Christenson, Lihue, HI (US)

Correspondence Address: TREX ENTERPRISES CORP., 10455 PACIFIC COURT, SAN DIEGO, CA, 92121, US

(73) Assignee: INCOMPLETE TREX ENTERPRISES CORP

(21) Appl. No.: 11/006,044

(22) Filed: Dec. 7, 2004

Related U.S. Application Data
(60) Provisional application No. 60/527,163, filed on Dec. 8, 2003.
(60) Provisional application No. 60/562,399, filed on Apr. 15, 2004.
(60) Provisional application No. 60/618,405, filed on Oct. 12, 2004.
(60) Provisional application No. 60/618,406, filed on Oct. 12, 2004.

(51) Int. Cl. C23C 16/00

(52) U.S. Cl. 427/248.1

(57) ABSTRACT

A method for forming within a reactor having a work zone of at least one cubic meter, composite articles particularly ceramic composites articles, for high temperature applications. The invention provides composite articles formed from the deposition on hot surfaces of a chemical vapor having entrained solid particles. A composite material is produced comprising a chemical vapor deposition matrix with the solid particles dispersed within the matrix. Applicants have designed reactors with work zones much larger than prior art CVC reactors greatly improving production efficiency. In a preferred embodiment the work zone volume is about 3.37 cubic meters. By carefully controlling the reactor gas flows and pressure within a large work zone, as well as the number of solid particles per flow rate of reactor gas, Applicants are able to efficiently produce composites with substantially improved quality as compared with CVD produced articles and as compared with articles produced with prior art CVC processes.

### CROSS REFERENCE TO RELATED APPLICATIONS

This application claims the benefit of provisional parent applications Ser. Nos. 60/527163, filed Dec. 8, 2003, 60/562399, filed Apr. 15, 2004, 60/618,405 filed Oct. 12, 2004 and Ser. No. 60/618,406 filed Oct. 12, 2004.

### BACKGROUND OF THE INVENTION

### FIELD OF INVENTION

The present invention relates to composite materials and especially to chemical vapor composites and to methods of making them.

### Composites

Composites are a class of materials that mix two or more distinct phases generally with the objective of achieving a mixture with improved properties such as improved mechanical or thermal properties. Composite technology has been used in a number of applications such as the production of structural components. For example, metal matrix composites (typically metal particles mixed with a ceramic base) can have desired performance features relating to high-temperature stability, chemical inertness, hardness and toughness. Composite design can also provide other desired properties relating to magnetic, electrical and optical features. It is often important to be able to control the microstructure (grain size and grain distribution). Composites can be produced utilizing high temperature treatment of liquid or solid phase mixtures, but with these processes control of grain size is difficult. In the case of ceramic and other high temperature composites, sintering agents are typically used to promote reactions of the separate components at reasonable temperatures. However, these agents act as impurities that may degrade performance of the resulting composite.

### Chemical Vapor Deposition

The direct application of solid materials to various substrates by chemical vapor deposition (CVD) is well known. For example, methyltrichlorosilane (CH₃SiCl₃) gas decomposes on contact with hot surfaces to SiC (a solid which plates out on the hot surfaces) and gaseous HCl, which is drawn off.

### Chemical Vapor Composites

U.S. Pat. Nos. 5,154,862 and 5,348,765 assigned to Applicants employer describe processes by which a composite article may be formed in a single step process from the coupling of a chemical vapor deposited matrix with a fine particle second phase embedded within the matrix. Such articles are formed at high deposition rates and may obviate the above-described prior art disadvantages. These prior art processes, known as chemical vapor composite (CVC) processes, utilize particles with sizes in the range of about 1 nm to 60 microns or larger with the particle mass comprising about 5 percent of the composite mass or greater, typically about 1 to 10 percent. With these prior art CVC processes deposition rates were much higher than CVD deposition rates but the densities of the resulting products were substantially reduced as compared to similar products produced with CVD processes. Prior art CVC processes utilize relatively small reactors having work zones smaller than one cubic meter. With the limited work zone volume and fact that composite runs generally require at least a few days to complete, the result is high costs of the composite products. In addition, prior art CVC processes have not provided techniques for good control of either composite density or grain size.

What is needed is a CVC method for efficiently producing ceramic composites with quality control of composite density and grain size.

### SUMMARY OF THE INVENTION

### Chemical Vapor Composites

### Chemical Vapor Deposition with Addition of Particles

The invention is a method for forming, within a reactor having a work zone of at least one cubic meter, composite articles, particularly ceramic composite articles, for high temperature applications. The invention provides composite articles formed from the deposition as a solid matrix on hot surfaces of a chemical vapor having entrained solid particles. A composite material is produced comprising the chemical vapor deposition matrix with the solid particles dispersed within the matrix. Applicants have designed reactors with work zones much larger than prior art CVC reactors greatly improving production efficiency. By carefully controlling the reactor gas flows and pressure within a large work zone, as well as the number of solid particles per flow rate of reactor gas, Applicants are able to efficiently produce composites with substantially improved quality as compared with CVD produced articles and as compared with articles produced with prior art CVC processes.

### Heated Substrates

The reactant gases referred to above must be heated to a temperature high enough to cause decomposition of the gas. A preferred technique is to fabricate an underlying material, a substrate, into a desired shape, such as a coil, wire or a more complex configuration such as a vane, turbo rotor, rocker arm, or other engine component. The shaped substrate is then maintained at the required elevated temperature, thereby providing the thermal activation necessary for the decomposition of the chemical precursor gas. The exact temperature range is dependent upon the ultimate CVD matrix composition selected.

### Precursor Gasses and Particles

A gaseous mixture containing the precursor gas, a carrier gas, and particles of the second phase material is then injected onto and over the heated substrate. The present invention can be utilized with a large number of precursor gasses to produce a variety of matrix materials. In this application 33 separate composite processes have been specifically identified. The particles of solid phase materials can be any of a large number of materials and shapes. Materials such as SiC, Si₃N₄, and ZrO₂ are examples of materials. Preferred shapes include random shaped particles of various mesh sizes, fibers, wiskers, nanoparticles and nanotubes.

### Silicon Carbide

A preferred composite material made by according to the present invention is silicon carbide composite materials. For example, a stream of methyltrichlorosilane and hydrogen is injected into the CVD chamber accompanied by a simultaneous flow of silicon carbide particles of 40-14,000 mesh. The gas mixture with the entrained particles is introduced into the reactor at a relatively low temperature. The CH₃SiCl₃ breaks down into solid SiC and gaseous HCl when the CH₃SiCl₃ gas contacts very hot surfaces in the reactor. The SiC along with some of the entrained particles deposits on the hot surfaces in the reactor, in particular graphite substrates having the general shape of desired articles. Gaseous HCl and hydrogen are pumped out of the reactor and disposed of. When desired thicknesses of the SiC-particle composite have been deposited, the reactor is cooled and the substrate with the coating of SiC-particle matrix is removed from the reactor. The substrate may then be removed leaving the SiC-particle composite article having qualities substantially superior to SiC deposited utilizing conventional CVD processes. The coated article thus produced contains a shaped underlying substrate fused to a CVD produced silicon carbide matrix having a uniform and random distribution of silicon carbide particles embedded therein.

### Large Reactor

Preferably, the reactor should have a work zone of at least one cubic meter for efficient production of a large number of small composite articles or the production of a smaller number of large items. A vertically oriented reactor is described with a cylindrical work zone 64 inches high and a diameter of 64 inches providing a work zone volume of 3.37 cubic meters and permitting production of large products or simultaneous production of a large number of small products. Large horizontally oriented reactors are also described specifically designed for the production of tubular shaped ceramic composites.

### BRIEF DESCRIPTION OF THE DRAWINGS

FIG. 1 is a side cross section view of a large reactor chamber showing important internal components;

FIG. 2 is a top cross section view of the reactor of FIG. 1;

FIG. 3 shows the heating elements of the reactor;

FIG. 3A shows a single heating element;

FIG. 4 is a drawing showing the flow of reactor gases and waste gas.

FIGS. 5A and 5B are side cross section views of important components of a preferred embodiment of the present invention.

FIG. 5C is a top cross section view of the components of the preferred embodiment.

FIGS. 6, 7, 8, 9 A-C and 10 show prior art techniques for making tubular CVC products.

FIG. 11 shows a technique for making 14 mirror blanks at the same time.

FIGS. 12A-C show a technique for making leading edge protection plates for a reentry vehicle.

FIGS. 13A-C show a technique for making a nose cone for a reentry vehicle.

FIGS. 14A and 14B show a technique for making multiple SiC tubes.

### DETAILED DESCRIPTION OF PREFERRED EMBODIMENTS

### Chemical Vapor Composite Process

### The Basic Process

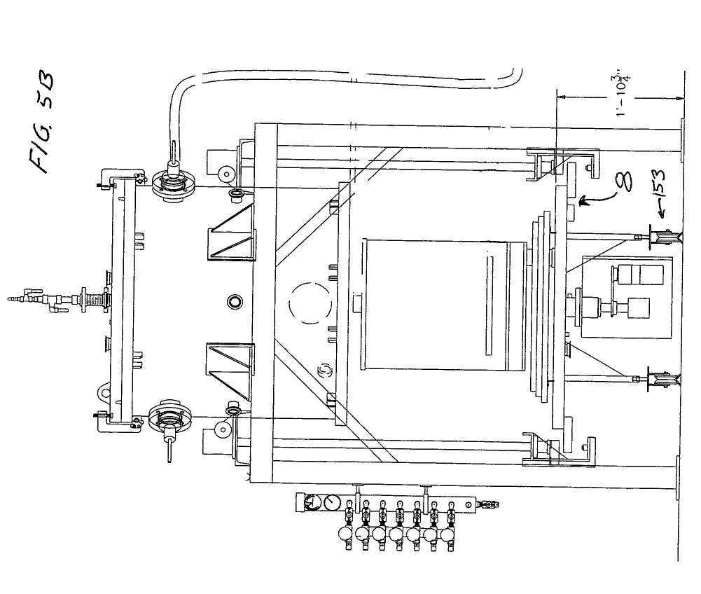

FIG. 4 is a drawing showing the basic elements utilized in preferred embodiments of the present invention. In this example, liquid CH₃SiCl₃ from source tank 156A is mixed with hydrogen from hydrogen generator 156B in vaporizer 156C where the liquid CH₃SiCl₃ is vaporized. Fine particles 170 from powder feeder 157 are driven by auger 157A and hydrogen pressure into the flow stream of the two feed gases CH₃SiCl₃ and hydrogen. Substrate 125 in reactor 102 is heated to temperatures in the range of 1200-1800 degrees C. When the CH₃SiCl₃ gas contacts the hot substrate, the gas is broken down to solid SiC which plates out on hot surfaces of the substrate as polycrystalline silicon carbide with the particles dispersed in a SiC vapor deposit matrix to form a silicon carbide composite layer having a polycrystalline silicon carbide matrix containing the fine particles. HCl is released as a gas. The HCl gas is trapped in scrubber 171 where it is mixed with spray water from spray 171A and converted to aqueous hydrochloric acid 171B which in turn is reacted with a sodium hydroxide solution from tank 173 to produce salt water (NaCl(aq)) 172A in tank 172. The salt water is disposed of.

### The Reactor Chamber

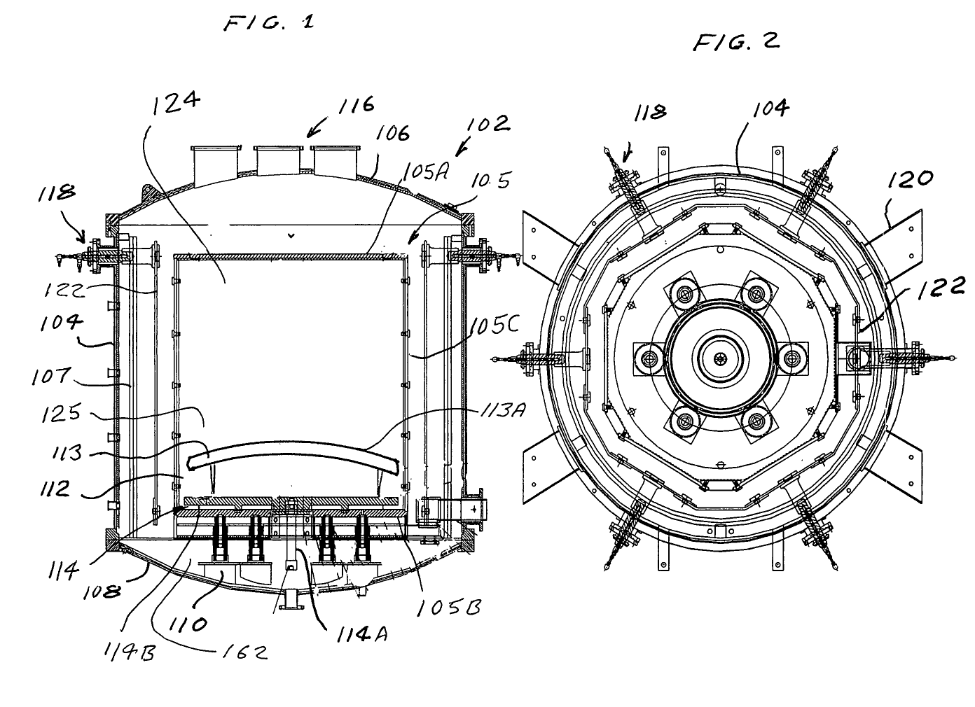

FIG. 1 shows a side view of a cross section of a reactor chamber 102 utilized in preferred embodiments of the present invention.

Reactor Shell

A reactor shell is comprised of a 304L stainless steel cylinder 104, a rounded stainless steel top cover 106 and a rounded stainless steel bottom cover 108. The cylinder and both top and bottom covers utilize a double wall design. A 10 psig pressure relief device is provided on the chamber. Six power ports 118 are provided to accommodate electric power feed through assemblies for the heating elements 122. Twelve additional ports (not shown) are provided for the installation of instrumentation and control components. A water-cooled exhaust port is also provided on the chamber. The reactor shell is equipped with a cooling water jacket providing cooling water flow in the spaces between the two walls of the shell. The outside wall temperature of the reactor is maintained at about 25-35 degrees C. when internal work zone temperatures are at about 1400 degrees C. Thermal insulation consists of 2 inches of carbon felt on the side of the hot zone, and 3 inches of insulation on the top and bottom of the hot zone. The carbon felt is mounted on the inner surface of a stainless steel support cage assembly 107. Cooling water manifolds incorporating shut off capability on both the supply and return side are mounted to the chamber support frame. Flow sensors with adjustable minimum level settings are provided for each cooling circuit. Interlocks are provided for connection to the power supply and alarms.

Heat and Pressure

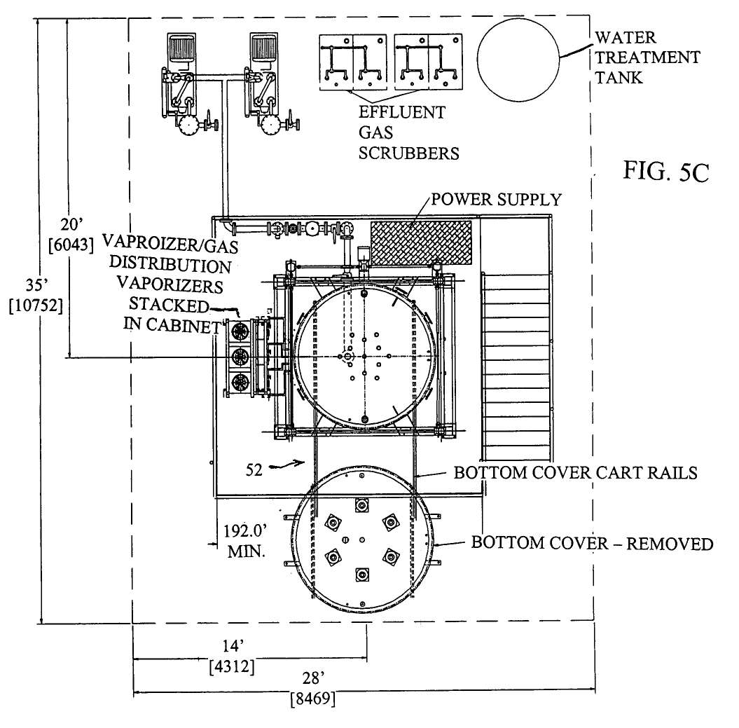

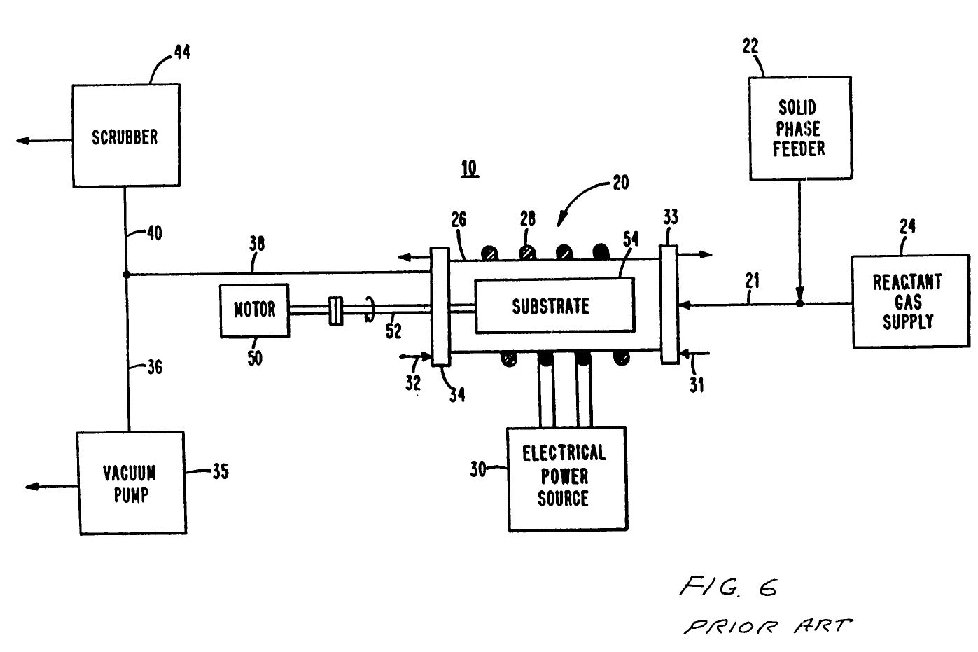

In preferred embodiments graphite heating elements 122 in reactor 102 heat the internal components of the reactor and the substrate material to temperatures of about 1200-1500 degrees C. prior to the injection of the feed gas-particle mix. Heating elements 122 are a three-phase resistance configuration for a balanced electrical loading. A modular design is utilized for easy part replacement during maintenance cycles to minimize downtime. A total of six water-cooled power feed through assemblies 118 are connected to the six graphite heating elements. A VRT type, low voltage, three phase power supply 160 as shown in FIG. 5A supplies power to heating elements 122 via water-cooled power cables 158. Micarta flanges provide electrical insulation from the grounded furnace chamber. A steady state holding power is approximately 170 KW, (excluding losses from gas flows). Power supply 160 comprises a 300 kva transformer to provide a 4-hour heat up time. The feed gas is preferably at about room temperature—is heated very rapidly when it comes in contact with hot (e.g., about 1400 degrees C.) surfaces within the work zone including the hot graphite substrate 113. The high temperature causes the CH₃SiCl3 to breaks down into SiC and HCl. The SiC along with some of the entrained particles deposits out on surfaces in the reactor, especially the graphite substrate 113. The internal components of the reactor are preferably graphite with carbon felt insulation. The reactor is capable of operation at temperatures up to 1600 degrees C. The typical heat up rate is 4 hours from room temp to 1400° C. Prior to operation the reactor pressure is drawn down to a vacuum of 1 torr with pump 142. This process takes about 60 minutes with pump 42 sized for about 300 atmospheric cubic feet per minute. Reactor vessel integrity is important. The chamber should be capable of passing a 10-6 standard cc/sec helium leak test.

Work Zone Enclosure

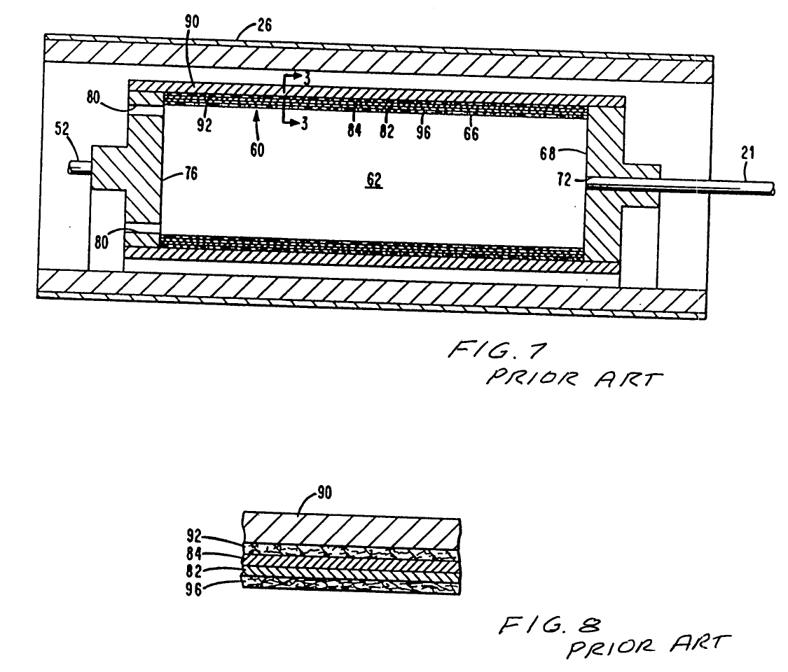

The chamber provides a 64 inch internal diameter, 64 inches high work zone 124 providing a volumetric work zone of about 3.37 cubic meters. The work zone is surrounded by a graphite enclosure 105 consisting of a bottom cover 105B, top cover 105A, and a graphite tube 105C assembly to keep the heating elements and thermal insulation clean to minimize maintenance. A uniquely designed exhaust region is included to minimize both un-reacted process gases and pyrophoric reactant byproduct downstream. The exhaust region is a subsidiary graphite compartment below the main chamber, separated by a graphite plate with between 6-12 exhaust holes. This compartment directs the exhaust gases to the exhaust plumbing along hot graphite surfaces which help to completely react any un-reacted pre-cursor gases or partially reacted subsidiary byproducts. The work zone enclosure and the bottom portion of the insulation can be lowered together with the bottom cover to allow easy access as shown in FIGS. 6A and 6B. Rotational mechanism 114 with shaft 114A is provided to achieve maximum deposition uniformity by rotating turntable 114B at rates of 0 to 10 rpm. The mechanism is capable of supporting up to 10,000 pounds. The large graphite components are preferably fabricated from PGX or CS grade graphite. CS grade components are incorporated in the chamber.

Reactor Frame

A steel frame 103, as shown in FIG. 5A supports the chamber, and a bottom cover lifting mechanism 150. Substrates on which composites are to be deposited are loaded into and unloaded from the work zone 124 through the bottom of the chamber as shown in FIGS. 5A and 5B. Frame 103 supports the reactor shell 4 at an elevated position and bottom cover 108 which can be lowered and raised with lifting mechanism 150. The bottom cover is lifted to the closed, operating position by an electrically operated lifting device mounted on the chamber support frame for stability and repeatable positioning. Location pins provided on the lifting mechanism ensures consistent proper alignment. The bottom cover may be rolled away from frame 103 from its lower position on “V” shaped wheels 153 rolling on railway system 152 (as shown in FIGS. 6A and 6B) that is mounted on the floor. Safe, efficient loading and unloading can be achieved via full 360 degree accessibility to the assembly when rolled away from the chamber.

Vapor Delivery System

A vapor delivery system consists of seven methyltrichlorosilane vaporizers 180 (with a total capacity of over 100 lbs/hr) and a gas flow distribution/measurement system, with safety interlocks and shut-off devices. Connections are provided for tie-ins to a liquid MTS source 156A, bulk hydrogen source 156B, bulk argon source (not shown), and utilities. Porter/Bronkhorst Mass flow controllers are included to provide accurate measurement and flow-control for consistent product quality. Seven injectors and interconnect piping are also included. Components of the vapor delivery system are enclosed in a ventilated hood (not shown). The pumping system is designed for extremely corrosive applications and is connected to a vacuum chamber 162 (as shown in FIG. 1) above the bottom cover through a manifold and air operated gate valves. The vacuum pump package is shown as a single pump in FIG. 4 but may consist of dual pumps. This vacuum pump package provides the process flow and is also used for purging and leak checking. Oil filtration and interlocks prevent oil back-streaming. A local pump control panel (not shown) will house the motor starters and heater overloads, and an interface to the main control for interlocks.

Instrumentation

Field instruments include 3 type C thermocouples for furnace temperature control, 7 type K thermocouples for vaporizer control, 14 mass flow controllers, 7 scales for vaporizers, 7 MTS mass flow controllers, 2 pressure transducers, 16 water flow switches and 4 local pressure gauges in the vaporizer cabinet. A PC based (LabView) control system is integrated into the system. The flow of CH₃SiCl₃ gas into reactor is monitored very accurately by measuring the flow rate of liquid CH₃SiCl₃ in the vaporizers.

Substrates

Silicon carbide composite parts are typically produced in reactor 102 by depositing the composites on graphite substrates having the general shape of the desired article to be produced. For example, as shown in FIG. 1, substrate 113 is a substrate for the making of a concave silicon carbide composite mirror. The top surface 113A of the graphite substrate is finely shaped and polished to the inverse of the shape of the desired mirror surface. After a sufficiently thick layer of silicon carbide is deposited on the substrate the substrate with its coating of silicon carbide is removed and the graphite is separated from the silicon carbide mirror. This mirror has a concave surface that may require very little polishing to produce the finished mirror. Differences in thermal contraction make the separation easy. For some shapes where the separation is not automatic or easy, the graphite substrate may be burned away.

Any material may be selected as the underlying substrates so long as it does not decompose at the required CVD temperature nor become subject to chemical reaction with the reactants or products of the process. It should be noted in this regard that the desired decomposition of CH₃SiCl₃ occurs at a temperatures greater than about 1300 degrees C., producing highly corrosive hydrochloric acid which can easily etch a plethora of common substrate materials. However, since the process of the invention is not solely directed at the decomposition of CH₃SiCl₃ into silicon carbide, but instead can be used with any matrix which can be produced through chemical vapor deposition, there will be a plurality of embodiments in which less corrosive gases will be produced at less elevated temperatures. In such embodiments, a broad range of materials may be incorporated as the underlying substrate without resulting in decomposition or corrosion during application of the disclosed process.

### Process Details

FIG. 4 shows the basic elements of a basic preferred process. A working gas CH₃SiCl₃ in a liquid form is pumped from tank 156A through flow control element 128 to vaporizer 180 where the CH₃SiCl₃ is vaporized and mixed with hydrogen gas. The hydrogen gas is produced by electrolytic separation of water in hydrogen gas generator 156B (Model HM 200, available from Teledyne Energy Systems) and the flow of hydrogen is controlled with flow control element 134. A typical feed gas flow would be about 400 standard liters per minute at about atmospheric pressure. The typical feed gas is 15 percent CH₃SiCl₃ and 85 percent hydrogen. Particles are added to the feed gas flow as shown in FIG. 4. Particles from particle feeder 170 are added at a controlled rate with auger 138 with some assist produced by a small pressure of hydrogen gas from gas pipe 140. A typical particle flow would be 50 grams per minute of SiC particles.

### Reactant Gasses

As described above, a preferred reactant gas employed in the formation of composite articles according to the invention is a mixture of methyltrichlorosilane (donor gas) and hydrogen (carrier gas), and a preferred particle material is silicon carbide. The mixture of reactant gas and entrained particles is made by introducing the particles and a carrier gas such as hydrogen from a powder feeder 157 into a stream of reactant gas carried by the line 121. The reactant gas and particles typically are supplied to the reactor 120 at or slightly (about 10 to 20 degrees C.) above room temperature. A continuous flow of particles from the feeder 157 is typically utilized to ensure a uniform build-up both of the CVD matrix produced from thermal activation of the reactant gas and of the particles which are co-deposited with the matrix. The particles may include long or short particles, or both, with selection dependent on the desired application of the composite article. Silicon carbide particles of 325-600 mesh size (dimensions of about 2 mils) have been found to be especially suitable in forming composite tubes.

### Alternative Gasses

In alternative embodiments precursor gases other than methyltrichlorosilane may be used to produce the SiC composite article of interest, provided a carbon containing precursor gas (e.g. hydrocarbons such as methane, propane, butane, etc.) and a silicon containing precursor gas (e.g., SiH₄, SiCl₄, SiHₓCl₄₋ₓ, etc.) are included. Reaction temperatures in these cases may range between about 800 to 1350 degrees C. For matrixes other than SiC as discussed in more detail below, the precursor gasses used are preferably those typically used in normal CVD processes to produce the matrix material.

### Tubular Products

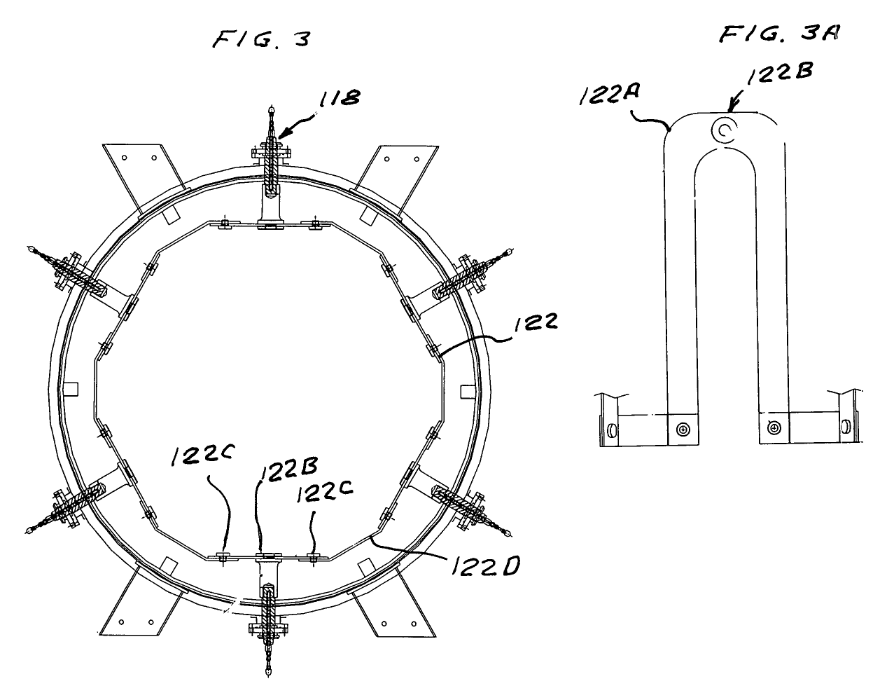

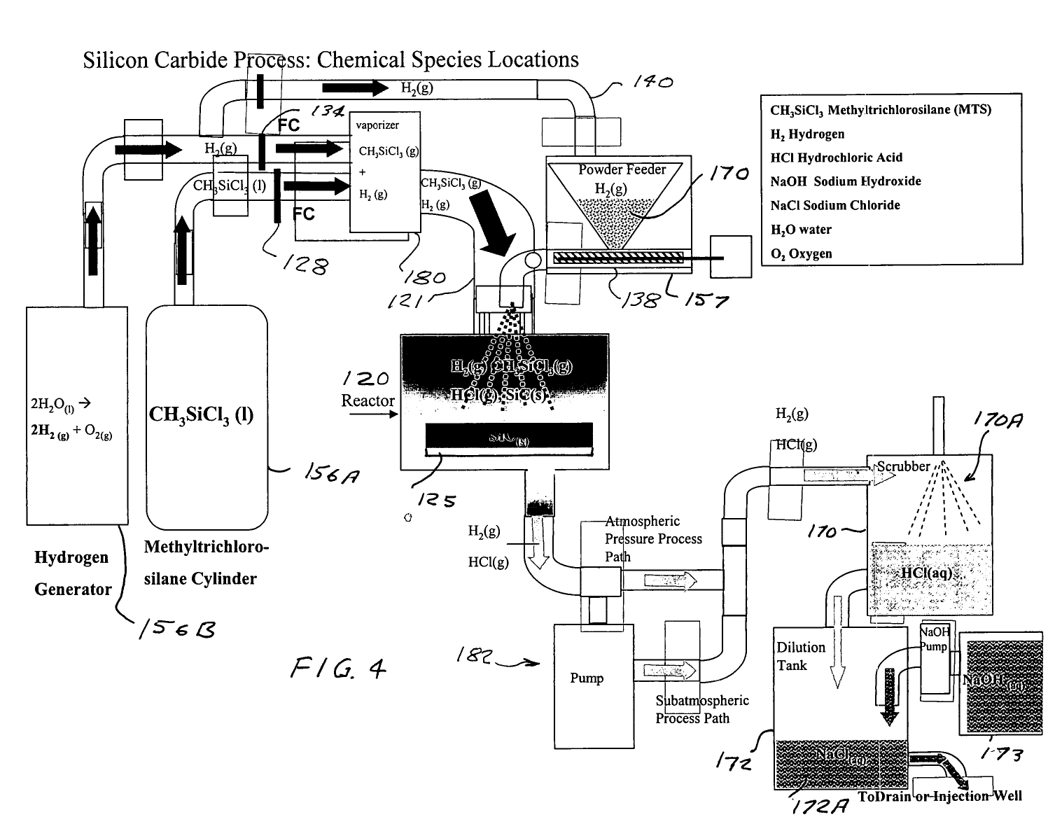

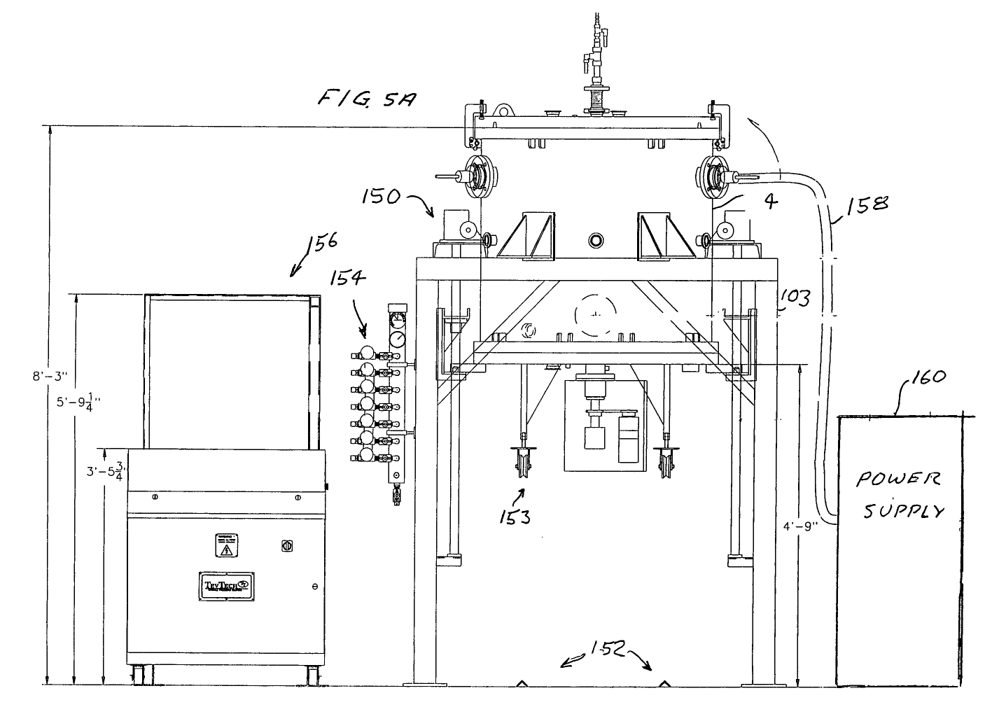

FIGS. 6, 7 and 8 are drawings showing a known technique for making tubular CVD products. These figures are FIGS. 1 and 2 in U.S. Pat. No. 5,154,862 assigned to Applicants' employer. However, the reactor can be expanded in size to provide a work zone of at least one cubic meter for more efficient production. This system is similar to the system shown in FIGS. 1-5C except that heating of the reactor is by induction and the gas flow is horizontal. For deposits on the inside of a tubular substrate the gas flow is axial through the substrate tube as indicated in FIG. 7. In this case the tubular substrate consists of graphite mandrel 90 flexible felt layer 92 and carbon paper tube 60.

These CVC processes utilize a reactor system 10 illustrated in FIG. 6 which includes a reactor 20 to which a mixture of particles or fibers and a reactant gas is supplied along a line 21 from a solid phase feeder 22 and a reactant gas supply 24. The reactor 20 may be a quartz reactor whose outer wall 26 is wrapped with an induction coil 28 connected to an electrical power source 30, and may be cooled by fans (not shown) and by cooling water introduced through appropriate lines 31 and 32 extending into end flanges 33 and 34. A vacuum pump 35 for evacuating the reactor 20 is connected to one branch 36 of an exhaust line 38, and a second branch 40 directs exhaust gases from the reactor 20 to a scrubber 44. Also connected to the reactor 20 are a motor 50 and shaft 52 employed to rotate a substrate 54 within the reactor 20 to insure even code position of materials on the substrate according to the method of the invention as set forth in more detail hereinafter. FIGS. 7 and 8 illustrate internal details of the reactor 20 and, by way of example, a hollow graphite tube 60 positioned in its reaction chamber 62 and on whose internal surface 66 a composite article may be formed. Adjacent to one end of the tube 60 is an end cap 68 having a passage 72 therein for the introduction into the reaction chamber 62 of a mixture of reactant gas and entrained particles or fibers. The opposite end of the tube is in contact with an end cap 76 having one or more ports 80 for removal of exhaust products from the reactor 20.

Substrate Structures

Tube 60 or other shaped structure on whose surface a chemical vapor deposition matrix and solid particles or fibers are co-deposited to form a composite article according to the invention may be of graphite in the form of carbon paper such as Grafoil paper, a product of Union Carbide Corporation. The carbon paper can easily be rolled into a tube and then sealed at various points along its length. If desired, two layers 82, 84 of carbon paper may be used and only the outer layer 84 removed upon completion of the co-deposition process leaving the inner layer 82 fused to the composite tube as an additional means of structural support.

If carbon paper is utilized as the substrate for co-deposition, a hollow graphite mandrel 90 of shape similar to that of the paper may be provided to support the paper during the process, with the mandrel ends in turn being supported by the end caps 68 and 76. An annular layer 92 of felt or other flexible material may also be included between the mandrel 90 and the carbon paper tube 60 to help maintain desired dimensional restrictions and to facilitate removal of the composite article from the reactor 20 upon completion of co-deposition.

Process Parameters

In the reactor 20 the substrate layers are heated to a temperature in the range of about 1200 to 1350 degrees C. The heated carbon tube 60 thermally activates the reactant gas entering through pipe 21, forming CVD vapors which deposit as a matrix along the interior surface of the carbon tube 60. For example, if a mixture of methyltrichlorosilane and hydrogen is employed as the reactant gas, SiC vapors and HCl gas are formed and the SiC is deposited on the inner layer 82 of carbon paper as a solid matrix. Particles (e.g., silicon carbide) from feeder 22 are co-deposited randomly and generally uniformly in the matrix to form the composite deposit on the surface of substrate 54. Exhaust products of the reaction, which include the corrosive gas HCl (and may also include Cl₂) flow out of the reactor 20 through exit ports 80 and exhaust line 38.

Producing a Tube Shape

During the co-deposition the carbon tube 60 and the mandrel 90 is preferably rotated to assure uniform deposition of the composite material around the circumference of the tube 60. After deposition is complete, the tube 60 and composite article 96 may readily be separated from the mandrel 90 by removing the end cap 76 and sliding the tube along the mandrel. If removal of one or both layers of the carbon tube 60 is also desired, it may then be burned or sand-blasted away from the composite article 96. The resulting article, since it has the dimensions and surface finish of the carbon tube 60 or other shaped structure, should require little or no machining to produce a final product. Moreover, because of the presence of particles within the SiC matrix, the composite article typically has greater strength and fracture toughness than a comparable CVD-only product.

Outside Surface Deposition on Structures with Rotational Axis Symmetry

A preferred application of this CVC method is the production of ceramic products by deposition on the outside surfaces a wide variety of rotationally symmetric shapes. For example the substrate can possess geometric complexity, and the deposited material will conform to this complex structure. For example, the substrate may be a rod that has spiral rifling, channels, or thread features. It is in this manner that free standing near net shape inside surface components can be produced. For these products the preferred reactor is a horizontal tube chemical vapor deposition reactor as shown in FIG. 6. The substrate assembly consists of a graphite substrate supported on both ends by graphite rods. These rods are supported on both ends by strut assemblies. The strut assemblies position the rod/substrate assembly in the middle of the deposition tube. The reactant gas and particle mixture flow through the deposition tube parallel to and around the substrate. In some cases a rod shaped graphite mandrel covered with a carbon paper tube is used to provide the substrate. A uniform deposition is achieved by rotating the carbon paper covered mandrel. After the required deposition time, the assembly is disassembled and the supporting rods and the ends of the coated substrate are cut off as required. The graphite mandrel can be slipped out from within the surrounding material and carbon paper substrate is then removed via an oxidation method leaving a silicon carbide composite tube.

Inside Surface Deposition of Structures with Rotational Axis Symmetry

The substrate can be a graphite sleeve or liner that fits into a graphite deposition tube. The reactant gas and particle mixture flows through the inside of the graphite substrate liner all as shown in FIGS. 6 and 7. A uniform deposit is achieved by rotating the deposition tube and the substrate liner. The ceramic material is deposited on the inside surface of the graphite liner. After the required deposition time the assembly is disassembled and the ends of the coated liner are cut off as required and the liner in pulled out from the deposition tube. The graphite substrate is then removed via an oxidation method.

Angled Tube Structures

Applicants have developed processes for producing angled tube sections composed of CVD derived materials. They use the CVC processes to coat the outside surface of a solid graphite substrate in a horizontal tube reactor. The substrate is machined so that the the outside surface of the substrate corresponds to the desired internal surface dimensions of the finished SiC product. The substrate is mounted in the deposition chamber so that the reactant gases (and particle additives in the CVC version) flow approximately parallel to the substrate surfaces. After deposition, the graphite substrate material is removed via combustion in a furnace, or via another oxidation method. This process provides a CVC material angled tube section that is near uniform in wall thickness and precise in internal radius dimensions.

### Composite Coatings on Products

CVD produced material with solid particles suspended therein has been successfully deposited onto flat, square, rectangular, cylindrical, and spherical substrates. These composite layers of CVD matrix and particles uniformly and randomly disposed within the matrix provide a hard, impact and corrosion-resistant covering for otherwise soft materials which are readily susceptible to chemical attack. Hence, relatively common materials such as tungsten, molybdenum and carbon can be manufactured into a final desired embodiment and then subjected to coating with silicon carbide composite utilizing one of the above disclosed methods. The result is a relatively inexpensive produce with an extremely hard, chemically resistant product.

### CVC Products Other than SiC

The present invention is not limited to a specific CVC produced material, such as CVC silicon carbide, but could additionally include other carbides (HfC, TaC, WC, B₄C, etc.), nitrides (Si₃N₄, BN, HfN, AlN, etc.), oxides (SiO₂, Al₂O₃, HfO₂, Ta₂O₅, TiO₂, BaTiO₃, SrTiO₃), silicides (WSi₂, TiSi₂, etc.), and metals (Cu, Al, W, Fe, etc.). Thus the scope of the matrix material which can be produced by the present invention is limited only by the capability of the chemical vapor deposition process to produce the desired chemical composition. However, the present invention provides for the addition of particles as described above that are deposited along with the vapor deposited material. Examples of matrix materials that can be produced utilizing the principals of the present invention are listed in the Table I below which includes preferred precursor gasses as well as preferred solid particulate materials.

TABLE I
Chemical Vapor Composites Processes

| | | | Solid Particulate Phase Added |
|---|---|---|---|
| | | Chemical Route | (*principal additive for grain growth |
| No. | CVD Matrix | (*preferred) | renucleation). |
| 1 | Silicon | *CH₃SCl₃ → SiC + 3 | SiC*, Si₃N₄, ZrO₂, carbon fibers, |
| | Carbide | HCl | carbon nanotubes, SiC fibers, SiC |
| | SiC | | whiskers. Any compatible solid. |
| 2 | Silicon | *3SiCl₄ + 4NH₃ → | Si₃N₄*, SiC, ZrO₂, carbon fibers, |
| | Nitride | Si₃N₄ + 12 HCl | carbon nanotubes, SiC fibers, SiC |
| | Si₃N₄ | | whiskers. Any compatible solid. |
| 3 | Boron | *BCl₃ + NH₃ → BN + 3HCl | BN*, SiC, Si₃N₄, ZrO₂, carbon fibers, |
| | Nitride | | carbon nanotubes, SiC fibers, SiC |
| | BN | | whiskers. Any compatible solid. |
| 4 | Aluminum | *AlCl₃ + NH₃ → AlN + 3 | AlN*, BN, SiC, Si₃N₄, ZrO₂, carbon |
| | Nitride | HCl | fibers, carbon nanotubes, SiC fibers, SiC |
| | AlN | | whiskers. Any compatible solid. |
| 5 | Hafnium | *2 HfCl₄ + N₂ + 4H₂ → | HfN*, SiC, carbon fibers, carbon |
| | Nitride | 2HfN + 8 HCl | nanotubes, SiC fibers, SiC whiskers. Any |
| | HfN | | compatible solid. |
| 6 | Niobium | *2 NbCl₄ + N₂ + 4H₂ → | NbN*, HfN, SiC, carbon fibers, |
| | Nitride | 2NbN + 8 HCl | carbon nanotubes, SiC fibers, SiC |
| | NbN | | whiskers. Any compatible solid. |
| 7 | Zirconium | *ZrCl₄ + 2BCl₃ + 5H₂ → | ZrB₂*, HfB₂, ZrC, HfC, TaC, SiC, |
| | Diboride | ZrB₂ + 10 HCl | carbon fibers, carbon nanotubes, SiC |
| | ZrB₂ | | fibers, SiC whiskers. Any compatible |
| | | | solid. |
| 8 | Zirconium | 1. Zr + 2Cl₂ → ZrCl₄ | ZrB₂*, HfB₂, ZrC, HfC, TaC, SiC, |
| | Diboride | 2. ZrCl₄ + 2BCl₃ + 5H₂ | carbon fibers, carbon nanotubes, SiC |
| | ZrB₂ | → ZrB₂ + 10 HCl | fibers, SiC whiskers. Any compatible |
| | | | solid. |
| 9 | Zirconium | 1. Zr + 4HCl → ZrCl₄ + 2H₂ | ZrB₂*, HfB₂, ZrC, HfC, TaC, SiC, |
| | Diboride | 2. ZrCl₄ + 2BCl₃ + 5H₂ | carbon fibers, carbon nanotubes, SiC |
| | ZrB₂ | → ZrB₂ + 10 HCl | fibers, SiC whiskers. Any compatible |
| | | | solid. |
| 10 | Zirconium | Zr(BH₄)₂ → ZrB₂ + 4 | ZrB₂*, HfB₂, ZrC, HfC, TaC, SiC, Si₃N₄, |
| | Diboride | H₂ | ZrO₂, carbon fibers, |
| | ZrB₂ | | carbon nanotubes, SiC fibers, SiC |
| | | | whiskers. Any compatible solid. |
| 11 | Hafnium | *HfCl₄ + 2BCl₃ + 5H₂ | HfB₂*, ZrB₂, ZrC, HfC, TaC, SiC, |
| | Diboride | → HfB₂ + 10 HCl | carbon fibers, carbon nanotubes, SiC |
| | HfB₂ | | fibers, SiC whiskers. Any compatible |
| | | | solid. |
| 12 | Hafnium | 1. Hf + 2Cl₂ → HfCl₄ | HfB₂*, ZrB₂, ZrC, HfC, TaC, SiC, |
| | Diboride | 2. HfCl₄ + 2BCl₃ + 5H₂ | carbon fibers, carbon nanotubes, SiC |
| | HfB₂ | → HfB₂ + 10 HCl | fibers, SiC whiskers. Any compatible |
| | | | solid. |
| 13 | Hafnium | 1. Hf + 4HCl → HfCl₄ + 2H₂ | HfB₂,* ZrB₂, ZrC, HfC, TaC, SiC, Si₃N₄, |
| | Diboride | 2. HfCl₄ + 2BCl₃ + 5H₂ | ZrO₂, carbon fibers, carbon nanotubes, |
| | HfB₂ | → HfB₂ + 10 HCl | SiC fibers, SiC whiskers. Any |
| | | | compatible solid. |
| 14 | Tantalum | *TaX₄ + B₂H₆ → TaB₂ + 4 | TaB₂*, ZrB₂, HfB₂, ZrC, HfC, TaC, SiC, |
| | Diboride | HX + H₂ | Si₃N₄, ZrO₂, carbon fibers, carbon |
| | TaB₂ | X = Cl, Br. | nanotubes, SiC fibers, SiC whiskers. Any |
| | | | compatible solid. |
| 15 | Titanium | *TiCl₄ + 2BCl₃ + 5H₂ → | TiB₂*, ZrB₂, HfB₂, ZrC, HfC, TaC, SiC, |
| | Diboride | TiB₂ + 10 HCl | carbon fibers, carbon nanotubes, SiC |
| | HfB₂ | | fibers, SiC whiskers. Any compatible |
| | | | solid. |
| 16 | Boron | *4BCl₃ + CCl₄ + 8 H₂ | B₄C*, TiB₂, ZrB₂, HfB₂, ZrC, HfC, TaC, |
| | Carbide | → B₄C + 16 HCl | SiC, carbon fibers, carbon nanotubes, |
| | B₄C | | SiC fibers, SiC whiskers. Any |
| | | | compatible solid. |
| 17 | Boron | 4 BCl₃ + CH₄ + H₂ → | B₄C*, TiB₂, ZrB₂, HfB₂, ZrC, HfC, TaC, |
| | Carbide | B₄C + 12 HCl | SiC, carbon fibers, carbon nanotubes, |
| | B₄C | | SiC fibers, SiC whiskers. Any |
| | | | compatible solid. |
| 18 | Zirconium | *ZrCl₄ + CH₃Cl + H₂ → | ZrC*, ZrB₂, HfB₂, HfC, TaC, SiC, carbon |
| | Carbide | ZrC + 5 HCl | fibers, carbon nanotubes, SiC fibers, SiC |
| | ZrC | | whiskers. Any compatible solid. |
| 19 | Zirconium | 1. Zr + 2Cl₂ → ZrCl₄ | ZrC,* ZrB₂, HfB₂, HfC, TaC, SiC, |
| | Carbide | 2. ZrCl₄ + CH₃Cl + H₂ | carbon fibers, carbon nanotubes, SiC |
| | ZrC | → ZrC + 5 HCl | fibers, SiC whiskers. Any compatible |
| | | | solid. |
| 20 | Zirconium | 1. Zr + 4HCl → ZrCl₄ + 2H₂ | ZrC,* ZrB₂, HfB₂, HfC, TaC, SiC, |
| | Carbide | 2. ZrCl₄ + CH₃Cl + H₂ | carbon fibers, carbon nanotubes, SiC |
| | ZrC | → ZrC + 5 HCl | fibers, SiC whiskers. Any compatible |
| | | | solid. |
| 21 | Zirconium | ZrBr₄ + CH₄ → ZrC + 4 | ZrC,* ZrB₂, HfB₂, HfC, TaC, SiC, Si₃N₄, |
| | Carbide | HBr | ZrO₂, carbon fibers, carbon nanotubes, |
| | ZrC | | SiC fibers, SiC whiskers. Any |
| | | | compatible solid. |
| 22 | Hafnium | *HfCl₄ + CH₃Cl + H₂ → | HfC*, ZrB₂, HfB₂, ZrC, TaC, SiC, carbon |
| | Carbide | HfC + 5 HCl | fibers, carbon nanotubes, SiC fibers, SiC |
| | HfC | | whiskers. Any compatible solid. |
| 23 | Hafnium | 1. Hf + 2Cl₂ → HfCl₄ | HfC*, ZrB₂, HfB₂, ZrC, TaC, SiC, carbon |
| | Carbide | 2. HfCl₄ + CH₃Cl + H₂ | fibers, carbon nanotubes, SiC fibers, SiC |
| | HfC | → HfC + 5 HCl | whiskers. Any compatible solid. |
| 24 | Hafnium | 1. Hf + 4HCl → HfCl₄ + 2H₂ | HfC,* ZrB₂, HfB₂, ZrC, TaC, SiC, |
| | Carbide | 2. HfCl₄ + CH₃Cl + H₂ | carbon fibers, carbon nanotubes, SiC |
| | HfC | → HfC + 5 HCl | fibers, SiC whiskers. Any compatible |
| | | | solid. |
| 25 | Tantalum | *CH₄ + Ta → TaC + 2H₂ | TaC*, ZrB₂, HfB₂, ZrC, HfC, TaC, SiC, |
| | Carbide | Preferred for conversion | Si₃N₄, ZrO₂, carbon fibers, carbon |
| | TaC | of surface layer of | nanotubes, SiC fibers, SiC whiskers. Any |
| | | existing Ta solid phase. | compatible solid. |
| 26 | Tantalum | *1. Ta + 2 Cl₂ → TaCl₄ | TaC*, ZrB₂, HfB₂, ZrC, HfC, TaC, SiC, |
| | Carbide | 2. TaCl₄ + CH₃Cl + H₂ | carbon fibers, carbon nanotubes, SiC |
| | TaC | → TaC + 5 HCl | fibers, SiC whiskers. Any compatible |
| | | Preferred for thick TaC | solid. |
| | | deposits. | |
| 27 | Titanium | *TiCl₄ + CH₄ → TiC + 4 | TiC*, ZrB₂, HfB₂, ZrC, HfC, TaC, SiC, |
| | Carbide | HCl | Si₃N₄, ZrO₂, carbon fibers, carbon |
| | TiC | | nanotubes, SiC fibers, SiC whiskers. Any |
| | | | compatible solid. |
| 28 | Tungsten | *WCl₆ + CH₄ + H₂ → | WC*, ZrB₂, HfB₂, ZrC, HfC, TaC, SiC, |
| | Carbide | WC + 6 HCl | carbon fibers, carbon nanotubes, SiC |
| | WC | | fibers, SiC whiskers. Any compatible |
| | | | solid. |
| 29 | Tungsten | WF₆ + CH₃OH + 2H₂ | WC*, ZrB₂, HfB₂, ZrC, HfC, TaC, SiC, |
| | Carbide | → WC + 6 HF + H₂O | carbon fibers, carbon nanotubes, SiC |
| | WC | | fibers, SiC whiskers. Any compatible |
| | | | solid. |
| 30 | Chromium | *7 CrCl₄ + C₃H₈ + 10 | Cr₇C₃*, WC, ZrB₂, HfB₂, ZrC, HfC, |
| | Carbide | H₂ → Cr₇C₃ + 28 HCl | TaC, SiC, carbon fibers, carbon |
| | Cr₇C₃ | | nanotubes, SiC fibers, SiC whiskers. Any |
| | | | compatible solid. |
| 31 | Tungsten W | *WCl₆ + 3 H₂ → W + 6 | W*, ZrB₂, HfB₂, ZrC, HfC, TaC, SiC, |
| | | HCl | carbon fibers, carbon nanotubes, SiC |
| | | | fibers, SiC whiskers. Any compatible |
| | | | solid. |
| 32 | Tungsten W | W(CO)₆ → W + CO | W*, ZrB₂, HfB₂, ZrC, HfC, TaC, SiC, |
| | | | Si₃N₄, ZrO₂, carbon fibers, |
| | | | carbon nanotubes, SiC fibers, SiC |
| | | | whiskers. Any compatible solid. |
| 33 | Diamond C | CH₄ → C + 2 H₂ | C (diamond)*, SiC, any compatible solid |

### Control of Deposit Density/Porosity

The incorporation of particles can lead to porosity in the deposit due to incomplete formation of the CVD matrix around the particles. Applicants have discovered that this porosity depends on the feed rate of particulate compared to the CVD matrix growth rate. The porosity of the CVC deposit can thus be controlled by adjusting the feed rate of the particulate from a fully dense deposit to a deposit with as much as 40% porosity, as desired by the specific application. Other deposition parameters also play a role by affecting the CVD matrix growth, including pressure, gas flows and substrate temperatures.

### Rate of Deposition

It is an important advantage of the invention that this co-deposition occurs at a high rate—e.g., 10-20 mils/hour as contrasted with about 2-5 mils/hour in a conventional process depositing silicon carbide by CVD only. Conventional CVD requires the use of low growth rates to minimize internal stress levels. The distinct grain structure afforded by the additional of particles results in a low stress deposit enabling much higher reactant feed rates than is achievable by conventional CVD.

### Radial Injection

The CVD gas stream and second phase particles or fibers entrained therein may be directed by an injector 200 onto the interior surface of a selectively shaped hollow mandrel 202 as is illustrated in FIGS. 9A through 9C. Injection tube 200 or substrate 202 is preferably rotated to assure even circumferential deposition. Radial injection as shown in FIG. 9A can be utilized to assure uniform deposition in the axial direction. Thermal decomposition of the reactant gas stream produces a composite 204 of a CVD matrix having a uniform distribution of the second phase material within the matrix, which is deposited along the interior surface of the hollow mandrel. Subsequent removal of the graphite mandrel from the composite results in a near-net shape composite 204 having a surface finish and configuration conforming to the internal surface of the mandrel. Such a process may be suitable for the manufacture of automotive engine components and jet engine components such as jet turbine vanes and other irregularly shaped articles requiring corrosion resistance, high strength, and toughness at elevated temperatures.

### Deposition on Exterior Surfaces

The method can also be successfully used to form composite articles on the exterior surface of a mandrel, rather than the interior surface, if such a final surface configuration is desired. All that is required of the surface upon which the CVD material is to be deposited is that it be thermally activated in order to initiate and drive the decomposition process of the pre-cursor gas, and that it be compatible with the gases and solid phase material to which it is exposed.

### Preheating of Solid Phase Material

FIG. 10 shows an alternative arrangement according to the invention in which the solid phase material and carrier gas are directed to reactor 220 along line 210 separate from line 212 carrying the reactant gas from supply 224. A pre-heater 216 is included between feeder 222 and reactor 220 to heat the solid phase material to a selected temperature; e.g., to a temperature as high as the deposition temperature of the substrate within reactor 220. Also a suitable device (not shown) for mixing the solid phase material and reactant gas within the reactor may be provided as part of this alternative arrangement. Such preheating of the particles or fibers prior to their introduction into the reactor enhances the thermal activation of the reactor gas in the reactor and may produce higher deposition rates, greater uniformity of the composite material, and/or enhanced mechanical properties of the resulting composite article than are achievable by use of a single stream of reactant gas and solid phase material. In this regard it should be noted that preheating of a combined stream of reactant gas and entrained solid phase material would be limited by the need to avoid premature thermal activation of the reactant gas which could lead to deposition in, and clogging of, a supply line or injection nozzle through which the reactants were supplied to the reactor.

### Use of Nanoparticles

Particles with at least one dimension in the range of a few nanometers to a few tens of nanometers (called nanoparticles) may be substituted for the 30 micron particles referred to in the above descriptions. The nanoparticles may be carbon nanotubes, or nanotubes formed from silicon carbide or other metal carbides. Use of these nanoparticles in place of the much larger particles permit a very large increase in the number of particles for the same particle percentage in the resulting composite. Since the composite grain size is determined by the number of particles per composite volume, the larger number of particles mean smaller grain size. Applicants have determined that smaller grain size results in increased fracture toughness. Therefore, these ceramic nanocomposites have greater toughness than composites formed using larger particles or fibers. In addition, the use of nanoparticles can result in unique electrical and optical properties, for example, due to the phenomenon of quantum confinement. The deposition method is applicable to any ceramic material currently obtainable via a CVD process. Carbon nanotubes are known for their extremely high tensile strength, and therefore these nanotubes should engender high strength properties for the CVC phase, where the matrix may be silicon carbide, silicon nitride, or any other phase that can be derived via chemical vapor deposition.

### Reactor Generated Particles

Another preferred variation is one in which particles are generated within the CVD reactor itself, which are then incorporated within the CVD material. In doing so, the same stress relief as the CVC process is accomplished without the need for additional particles to the gas stream. The advantages achieved are higher purity and simplification of the reactor design, while maintaining high density, good mechanical properties, and high growth rates. Methyltrichlorosilane is preferably used as the reactant precursor for the growth of silicon carbide via CVD. MTS vapor is injected into a high temperature furnace at about 1300-1400° C. using a carrier gas of hydrogen. The SiC is deposited on a graphite perform, while simultaneously, SiC particulates are generated above the part. The furnace and preform are designed in the former process to lengthen the residence time of the chemical in the high temperature reaction zone. This serves to increase the probability of SiC particles nucleating from the gas phase. Through control over the pressure, temperature, and feed rates of MTS and H₂, the degree of particle formation can be controlled. Optimization of these parameters yields the desired amount of stress relief, while maintaining fully dense, low porosity material.

The technique can also be applied to other materials, including other carbides, nitrides, oxides, silicides and metals. There are a number of applications, which can benefit from the high purity, low porosity, low stress, and high mechanical strength of the ceramic materials deposited via this technique. Examples of these applications include optics, high purity chemical processes, and components for extreme high temperature environments.

### Batch Production Process for Tubes

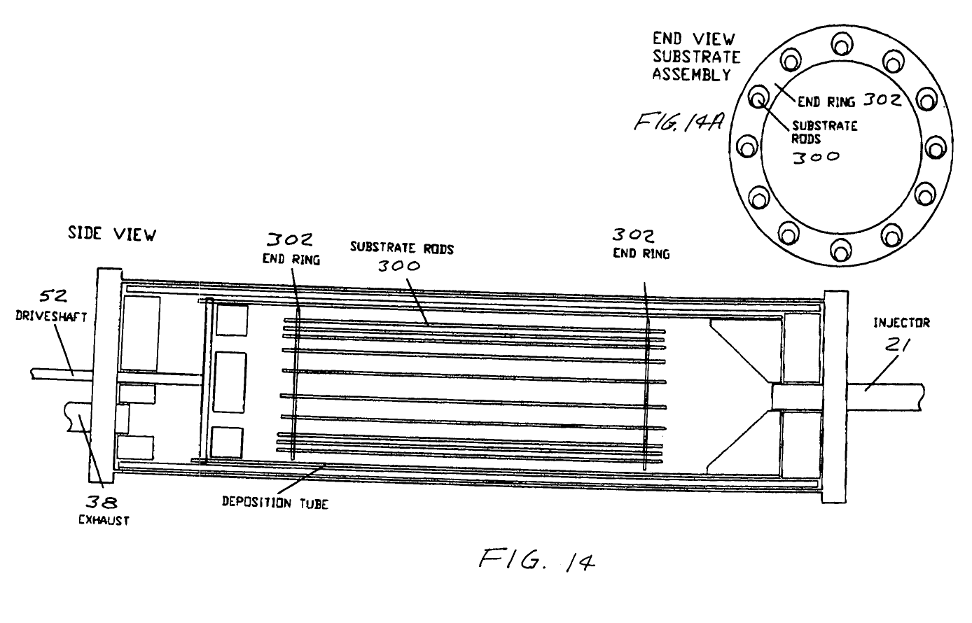

The present invention can be used for batch production of ceramic tubes in which multiple tubes are produced in a single run. The apparatus is a horizontal tube chemical vapor deposition reactor. The reactant gas mixture and particles enter the deposition zone via a water-cooled injector on one end and the resulting exhaust exits through the other. The substrate assembly consists of multiple graphite rods supported on each end by graphite rings 302 as shown in FIG. 14 and FIG. 14A. The end rings support the substrate rods in a manner that allows these rods to be spaced evenly around the inside of the graphite deposition tube. This is accomplished by providing a hole in each of the end rings for each substrate rod. The reactant gas mixture and particles flow from injector line 21 through the center of the deposition tube parallel to the substrate rods. A uniform deposit is achieved by rotating the entire deposition tube with drive 52 and also each substrate rod rotates in its respective holes. The independent rotation of each substrate rod is achieved by ensuring that the mounting hole in each end ring is sufficiently larger than the diameter of the substrate it supports as shown in FIG. 14A. As the deposition tube is rotating, each substrate rod also rotates independently and at a different rotation speed than the deposition tube itself. After the required deposition time, the assembly is disassembled, the ends of each coated rod it cut off at the desired length, and the graphite substrate removed via an oxidation method.

### Controlling Molecular Ratios with CVC Process

The chemical vapor composites method involves the addition of solid particulates (normally polycrystalline silicon carbide particles) to a chemical vapor deposition reaction stream. Molecular ratios can be varied using special process variations of the basic CVC process. In preferred embodiments particles other than polycrystalline silicon carbide can be added to the feed gas stream. These alternative added particles could include various forms of silicon carbide other than polycrystalline silicon carbide; single crystal silicon particles could be used, or mixtures of silicon carbide particles and silicon particles could be used. Also, the matrix material could be altered by using variations in the feed gas. For example, softer optical surfaces may be produced for mirrors that are more amenable to polishing. Thus, for the mirror substrate shown in FIG. 1, a preferred technique is to chemical vapor deposit a few microns thick layer of silicon using tetrachlorosilane gas (SiCl₄) in place of the CH₃SiCl₃ gas in the feed gas for the first few minutes of the deposition process. After the thin layer of silicon is laid down without particles, the active feed gas is switched to CH₃SiCl₃ to lay down the silicon carbide composite material. In some cases a combination of SiCl₄ and CH₃SiCl₃ may be used to produce a matrix with a high silicon content relative to carbon. This high silicon content facilitates bonding of the silicon carbide to a carbon rich substrate material. Variation of the free silicon content of the deposited material may also be achieved via the composition of the solid particle stream composition, and via control of specific process conditions such as temperature and the mole ratio of hydrogen gas to the CH₃SiCl₃ gas. Reducing the reactor temperature by 50-100° C. from the baseline SiC process increases the silicon ratio by 5-10%. Also, silicon ratio can be reduced further by reducing the mole ratio of hydrogen to CH₃SiCl₃ by 20-30%.

### Vertical Slats

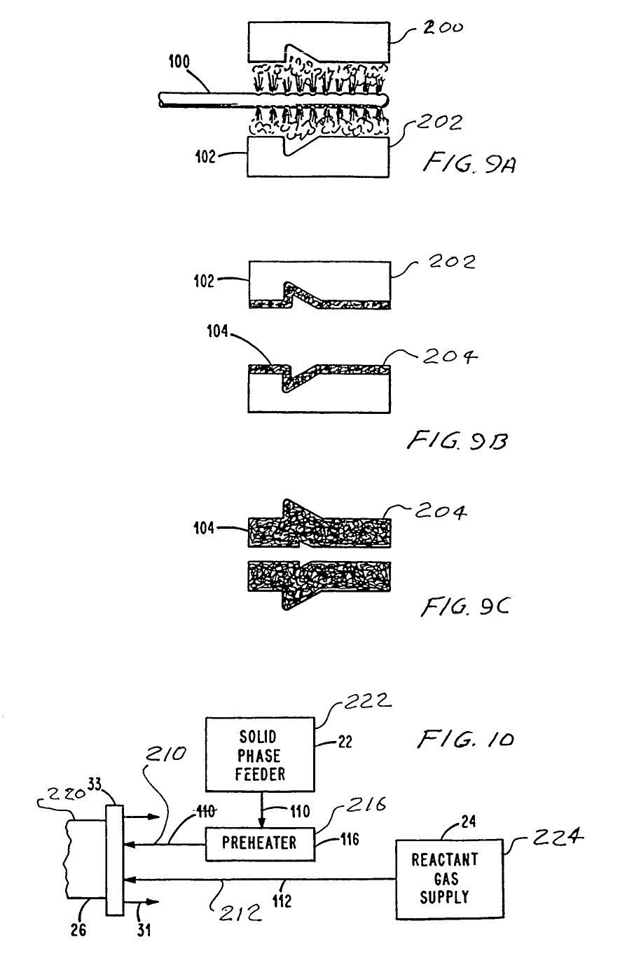

Applicants have developed techniques for producing multiple planar type SiC products during a single production run. Applicants multi-product technique is shown in FIG. 11. In this case seven 1.0 meter square flat substrate 113A are arranged vertically. SiC mirror elements are produced on both sides of each substrate. With this arrangement, 14 flat mirror elements can be produced simultaneously.

### Metal Boride, Carbide and Nitride Composites

The techniques and reactors described above can be modified slightly to produce metal boride composites, metal carbide composites and metal nitride composites, which are suitable, for example, for ultra high temperature applications. As in the case of the silicon carbide composites, solid particles are entrained in a feed gas stream and the particles are deposited on a substrate along with a matrix material that is vapor deposited from the feed gas. The proposed method is able to maintain the high purity required for ultra-high temperature applications, while achieving a low internal stress in the composites. Table I lists several of these composites along with preferred chemical routes and preferred particle and fiber materials.

Boride Family CVC

Preferred embodiments of the invention involves the production of metal boride ceramics via the general process:
MCl_{4(g)}+2BCl_{3(g)}+5H_{2(g)}→MB₂₍ₛ₎+10HCl_{(g)}
where M=Hf, Zr, Ta, or Ti, BCl₃ is boron trichloride, and H₂ is hydrogen gas. The metal chloride is introduced into the reaction stream by either direct sublimation of the solid, or via in process production of MCl₄ vapor from solid metal and a chlorine containing gas species. To the reaction mixture is added solid micron or nanometer scale particles, whose chemical composition is identical to the metal boride species being formed, or entirely different. This embodiment allows for the production of high purity residual stress free ultra high temperature metal boride ceramic materials.

Carbide Family CVC

Preferred embodiments of the invention involves the production of metal carbide ceramics via the general process:
MCl_{4(g)}+CH₃Cl_{(g)}+H_{2(g)}→MC₍ₛ₎+5HCl_{(g)}
where M=Hf, Zr, to Ta, CH₃Cl is chloromethane, and H₂ is hydrogen gas. The metal chloride is introduced into the reaction stream by either direct sublimation of the solid, or via in process production of MCl₄ vapor from solid metal and a chlorine containing gas species. To the reaction mixture is added solid micron or nanometer scale particles, whose chemical composition is identical to the metal boride species being formed, or entirely different. These embodiments allow for the production of high purity residual stress free ultra high temperature ceramic materials of the carbide family.

Nitride Family

Preferred embodiments of the invention involves the addition of solid particulates to a chemical vapor deposition reaction stream. This invention involves the production of metal nitride ceramics via the general process:
2MCl_{4(g)}+N_{2(g)}+4H_{2(g)}→2MN₍ₛ₎+8HCl_{(g)}
where M=Hf, Zr, to Ta, and N₂ and H₂ are nitrogen and hydrogen gas, respectively. The metal chloride is introduced into the reaction stream by either direct sublimation of the solid, or via in process production of MCl₄ vapor from solid metal and a chlorine containing gas species. To the reaction mixture is added solid micron or nanometer scale particles, whose chemical composition is identical to the metal boride species being formed, or entirely different. These embodiments provide for the production of high purity residual stress free ultra high temperature ceramic materials of the Nitride family.

### Variable Pressure

Net and near-net CVC deposition require effective mass transport of reactants into (and reaction products away from) the topography of the substrate. In certain substrate geometries, the growth of the deposited material results in a loss of mass transport efficiency to certain locations of the substrate. To minimize this result in some cases Applicants utilize variable reaction pressure to optimize process efficiencies and mass transport rates. In the early periods of the deposition, high reactor pressures may be employed because the complex substrate structure is considered “open” and facilitates efficient reactant and product mass transport. As the growth of the deposited material proceeds and significant constriction of reactant (product) flow to (from) certain locations in the structure occurs, the reaction pressure is systematically reduced to increase mass transport rates.

The advantage of this technique lies in the ability to optimize reactant flow rates with regard to mass transport and process efficiency. If high reactant pressures are employed throughout the deposition, certain locations within the complex structure will exhibit deposits that are thinner than desired. However, if low pressures are employed throughout the deposition, including the early periods when the complex structure is “open”, the process efficiency will be reduced due to the enhanced linear velocity of the reactant gases, with consequent losses of reactant to the exhaust system.

### Special Products Using CVC and Reactive Melt Techniques

The chemical vapor composite process and a reactive melt infiltration process can be used in conjunction to produce ceramic products having special shapes such as straight multi-section tubes, angled tubes or “elbows”, and tube sections in the form of a “tee”. Separate ceramic parts can be produced using the chemical vapor composite process. The finished ceramic sections will be ground (such as with either an internal or an external taper) so the individual components will fit tightly together to form the required shapes. The individual components are then bonded using a reactive melt infiltration process. Techniques for joining ceramic section via reactive melt are described in detail in various NASA publications available on the Internet.

### Thin Film Composite Materials

Composites may be produced comprising thin films of material consisting of two or more distinct phases, using physical transport of nanometer-scale particles along with a physical vapor deposition stream(s). Composite thin film materials, i.e., a film containing a mixture of two or more chemically distinct phases, can exhibit a wide variety of interesting properties, such as giant magneto-resistance, enhanced magnetic coercivities, and quantum well behavior. These properties arise from the interaction between the different phases, and depend strongly on the grain structure of the film, i.e., grain size, grain boundaries, and arrangement. The common method to form these composite films is to co-deposit material from separate sources by physical vapor deposition (PVD), followed by an anneal to achieve the desired grain structure. However, the annealing step gives limited control over the grain structure and can lead to undesired interdiffusion between the separate phases. The new technique is the formation of composite films by physical transport of nanometer scale particles to a substrate, coincident with a conventional chemical vapor stream. The added particles thus become embedded in the CVD matrix. The key advantage of this method is the ability to precisely control the grain size in each film, with minimal interdiffusion between the phases, since the requirement for high temperature anneal is removed. Various different films can be provided by changing to size and/or number of particles and/or changing the gas chemical or physical properties.

### Designed Stress

In this embodiment, a deliberate sequence of particle types is added to a chemical vapor deposition stream. The materials constituting the different particles are selected for their coefficients of thermal expansion (CTE). The added particle materials may have CTE values higher or lower than that of the matrix phase that is produced by the chemical reaction. The effective CTE of the particle-matrix composite will be a function of the CTE values of the matrix and particle materials. By controlling the volume fraction and type of particle material added to a given layer or local region of the deposited material, the magnitude and distribution of residual stresses in the deposited object can be controlled.

An example application would be the CVC deposition of silicon carbide, wherein the initial particle additives would be low CTE silicon nitride (Si₃N₄). After a selected period of SiC/Si₃N₄ composite growth, the particle additive is changed to high CTE zirconia (ZrO₂). After a selected period of SiC/ZrO₂ growth, the particle additive is changed back to Si₃N₄. Upon cooling, the differential CTE properties of the three composite layers in the deposit result in compressive surface stresses and tensile internal stresses. The effect is analogous to the condition accomplished in tempered glass, where rapid cooling of the surface layers of a molten sheet, followed by slow cooling of the interior results in compressive surface forces and a remarkable enhancement of fracture toughness. The example above assumes the final use temperature is lower than the deposition temperature. The CVC designed stress concept can also be employed to engender compressive surface stresses when the application temperature is higher than the deposit temperature.

### Continuous CVC

The chemical vapor composite process can be used to produce tube sections using a continuous deposition process. It is with this method that a tube can be produced that is longer than the chemical vapor reactor that it is produced in. The apparatus is a horizontal tube chemical vapor reactor. The reactive gas and particle mixture enters the deposition zone via a water-cooled injector from one end and the resulting exhaust exits through the other. The substrate preferably is a hollow graphite tube having a length slightly longer than the desired product length and much longer than the reactor chamber. The substrate is advanced through a pre-deposition zone where the substrate is heated to the deposition temperature before it enters the reactor. The substrate is advanced at a constant feed and rotation rate to achieve a uniform deposit. As portions of the coated substrate exits the reactor, the coated substrate passes through a cool-down zone where the deposit gradually cools to ambient temperature. By adding sections of hollow graphite tube substrate to the rear end of the tube, the length of the final SiC tube could be extended indefinitely.

### Controlled Resistivity of Semiconductor Materials

Using prior art CVC techniques the resulting composite material can have resistivities that can range anywhere from a few ohm-cm to a few thousand ohm-cm or more, depending on the defects and impurities in the material. Applicants have developed a method for controlling the resistivity of the chemical vapor composite by incorporating a dopant gas together with a particle stream and the chemical vapor stream. The resulting process has the advantages of high growth rates, superior mechanical properties and controllable resistivity. A preferred embodiment of the invention involves the use of methyltrichlorosilane (CH₃-SiCl₃) as the reactant gas for the SiC growth, micron size SiC particles as the solid phase, and either a trivalent dopant gas such as diborane (B₂H₆), boron trichloride (BCl₃), trimethyl aluminum ((CH₃)₃Al) or aluminum chloride (AlCl₃) or a pentavalent dopant gas such as ammonia (NH₃), nitrogen (N₂), or phosphine (PH₃). A key requirement for the successful control of the resistivity is the substitution of a fraction of the Si sites in the SiC lattice with the dopant atoms. Resistivity of the SiC can be controlled by adjusting the molar ratio and type of the dopant gas relative to the methyltrichlorosilane. A decrease in resistivity of 2-3 orders of magnitude has been observed using N₂ dopant with CVC SiC.

### Composite Ferroelectric Materials

Composite ferroelectric material may be produced using selected secondary phase particles with a reactive chemical vapor deposition stream. Ferroelectrics are a class of insulating materials, which can exhibit a spontaneous polarization whose direction can be changed via an applied electric field. The phenomenon is tied to the placement and symmetry of ions in a crystalline lattice, which can be altered by straining the material. A common method of producing ferroelectric materials is metal-organic chemical vapor deposition, which reacts a metal-organic complex at high temperature and under controlled conditions of pressure and gas composition to achieve the desired ferroelectric state. A ferroelectric with altered material properties can be produced by adding a second phase particulate stream to the metal-organic vapor stream. The strain state of the ferroelectric material can be changed by adding a particulate with a different coefficient of thermal expansion (CTE) than the ferroelectric. Upon cool down from the high deposition temperature, the particulate can introduce a tensile or compressive stress on the material, depending on the difference in CTE's between the particle and the ferroelectric. Anticipated benefits could include reduced dielectric loss materials, enhanced dielectric constant, and increased dielectric tunability.

### Tubular Filters

The chemical vapor composite process can be used to produce ceramic filters for high temperature applications. In a preferred embodiment ceramic fibers are added to the reactant gas mixture so as to be deposited in such a way that the fibers are overlapping and intertwined. There can be enough of a chemical vapor matrix to bond the fibers but not enough to form a dense deposit. As a result the composite can be made porous with the porosities that can be easily controlled by controlling the various parameters of the CVC process. The ceramic composite is preferably deposited on the inside of a tubular graphite substrate. The injection of the reactant gas mixture and the ceramic fibers can be controlled so the proper size of the passages through the porous composite can be achieved.

### Catalytic High Temperature Filter Stacks

This embodiment involves the addition of a particle stream that includes metallic or other species (macro, micro, or nanometer scale) that have catalytic activity for a given chemical process (e.g., platinum and palladium for the conversion of carbon monoxide to carbon dioxide, conversion of NOₓ to N₂ and H₂O). The chemical reactant stream would produce a high temperature matrix material (e.g., SiC, Si₃N₄) that would be structurally robust under conditions of extreme temperature and corrosive environments. The catalytically active particle additives would be exposed on at least one surface of the composite system, such that they would contact target molecular species in a process or exhaust stream. The novelty of the invention lies in the exceptional chemical and thermo-mechanical performance of the matrix CVC material, coupled with catalytically active inclusions.

### Porous Structures by Using Removable Particles

This embodiment involves the addition of a particulate stream that includes high aspect ratio fibers or whiskers. The chemical composition of these fibers or whiskers is such that they can be removed from the deposit structure via chemical etching or combustion. The matrix material produced by the chemical vapor deposition process is typically refractory metals or ceramics. Removal of the fiber/whisker components result in a structure of controlled porosity and pore size. The resulting structure can serve as a particle filter device for high temperature, highly corrosive environment applications.

### Transition Joints

In cases where a vapor deposition process is used to deposit a ceramic matrix on a substrate the present invention can be utilized to minimize stresses due to differences in thermal expansion between the substrate and the matrix material. In this case the particle material size and composition can be chosen for adjusting and grading the effective coefficient of thermal expansion of the deposited phase in order to improve bonding of the deposited phase with the substrate phase.

### Bragg Stack SiC Optics

As stated above silicon carbide is a superior material for lightweight mirror applications because of its high stiffness-density ratio, high thermal conductivity and low coefficient of thermal expansion. SiC is particularly favorable for space optics applications because of its resistance to plasma and radiation damage. While SiC is highly reflective in certain limited regions of the infrared spectrum, achieving high reflectivity in other spectral domains requires the addition of a highly reflective coating, for example a metal or dielectric stack structure, either of which may comprise a non-SiC material. Applicants propose to provide a synthesis of a highly reflective Bragg stack via electrochemical etching. The SiC material may be single crystal or polycrystalline and derived via chemical vapor deposition or chemical vapor composites methods. The SiC material may be either n-doped or p-doped to a level sufficient to allow electrochemical etching. The etching would be achieved using an ethanolic hydrofluoric acid solution under either potentiostatic or galvanostatic conditions. Repeated alternating exposures to high and low current densities (or anodic potentials) result in layers of alternating porosity and therefore alternating layers of varying index of refraction. By controlling the anodization current density and etching time for each layer, it is possible to prepare a multiple layer structure, where each layer fulfils a λ/4 condition necessary for high reflectivity over a selected wavelength range. The advantage of this technique lies in the dielectric Bragg stack being comprised of SiC material, rather than another substance with lower radiation and/or plasma tolerance.

### Heaters

Another preferred embodiment of the present invention provides a high-purity, high-oxidation resistant, durable heater element. The heater elements consist of heavily nitrogen or boron doped SiC produced using a reactant chemical vapor gas stream (e.g., methyltrichlorosilane plus hydrogen), along with a secondary particulate phase, together with a dopant gas of nitrogen, ammonia, or boron trichloride. Typical proportions of the gas flows may be 15% dopant, 75% hydrogen, and 10% methyltrichlorosilane. These separate ingredients come together upon a graphite mandrel. The heater can be produced in a variety of geometries, including tubular or planar, depending on the mandrel geometry. One of the major advantages of the proposed method is the ability to make a tougher heater material, via stress relief or particulate reinforcement, which is able to withstand a greater number of thermal cycles.

### Toughened Ceramics

Preferred embodiments of the present invention can be used to produce toughened ceramics. Fibers and/or whiskers can be added to the reactant gas mixture and injected into a chemical vapor deposition reactor. The fibers and/or the whiskers will be co-deposited to form a ceramic composite. The interweaving fibers serve as the medium to increase the strength of the composite. The added fibers will stop the progression of cracks.

### Annealing for Increased Thermal Conductivity

The basic CVC process produces grains of varying sizes. Applicants have discovered that grain sizes can be increased by adding an annealing step to the CVC process. For example after producing CVC material at the normal deposition temperature of about 1400 degrees C., Applicants increased the temperature in the reactor to 1700 degrees for two hours. Subsequent analysis indicated a significant growth in grain size and an approximately 20 percent increase in thermal conductivity, from about 200 Watts/mK to about 240 Watts/mK.

### Translucent CVC SiC

Applicant's CVC SiC can be made translucent through lowering the pressure to about 10 torr. This reduces the grain size to the point where the material transmits light. This material is potential useful for optical applications, such as conformal optics, missile nose cone, ballistic windows for aircraft and vehicles, and high temperature windows among many other applications. Applicants can produce large transparent surfaces, especially with the 3.37 cubic meter reactor shown in FIG. 1.

### Homogeneous Alloys and Composites

Preferred embodiments of the present invention involves the addition of nanometer sized solid particles to a CVD reaction stream, where the solid particle material and the material deposited through the CVD reaction represent components of a potential homogenous composite. The CVC deposition process results in a composite which is heterogeneous at the molecular scale, but homogenous at the nanometer scale. Because of the high surface—volume ratio of the additive nano-particles, the effective fusion temperature of these particles is lower than that of micron sized particles of the same material. Subsequent heat treatment leads to true homogeneous mixing of the two components. A key advantage of this process is that the composite material can be fabricated at a lower temperature than conventional processes, hence achieving a savings in energy and cost.

### Near Net Shapes Optical Structures

The CVC Process is capable of producing near net shape materials by replicating the surface of the mandrel very precisely. Through the proper selection and preparation of the mandrel material and surface, Applicants can replicate mirrors directly from the mandrel, completely eliminating conventional polishing of the resulting CVC SiC mirror, or at least greatly reducing the extent of the polishing. This is the Holy Grail for high-grade optics and provides important commercial advantages in both cost and quality in the production of mirrors.

### Continuous Controlled Sublimation

Chemical vapor deposition of structural materials requires a precise control over reactant feed rates. When a reactant is a gas at ambient temperatures, a standard gas flow controller can be used. When a reactant is liquid at ambient temperatures and pressures, a liquid vaporizer unit is typically employed, and the control over reactant feed rate is accomplished via control of liquid flow into the vaporizer, and a feedback system through which liquid flow in and vapor flow out maintain an approximately constant vaporizer mass.

If a reactant in a chemical vapor deposition scheme is solid under ambient conditions, reactant feed rate is difficult to control. In preferred embodiments of the present invention, the rate of sublimation is determined by heat and/or carrier gas flow rate into the sublimator unit. The rate of sublimation is monitored by a mass compensator system, namely a device that delivers a powder or a low vapor pressure liquid to a receptacle on the top of the sublimator unit. A scale monitors the mass of the sublimator and the added liquid or powder. A control loop delivers mass data to the heater and/or carrier gas controls. As more solid sublimes and leaves the unit, more compensating powder or liquid is added to maintain a constant mass. The rate at which the compensating powder or liquid is delivered to the receptacle is, under conditions of zero sublimator unit mass change, equivalent to the rate at which the sublimed material is being delivered to the reactor.

### Protective Plates for Reentry Vehicles

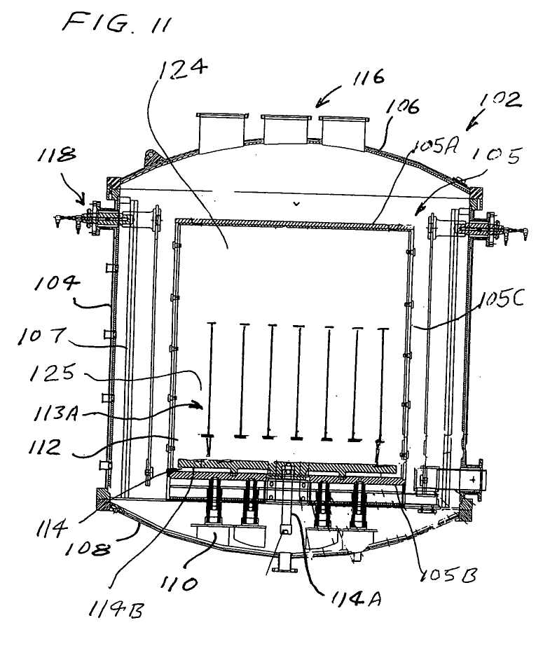

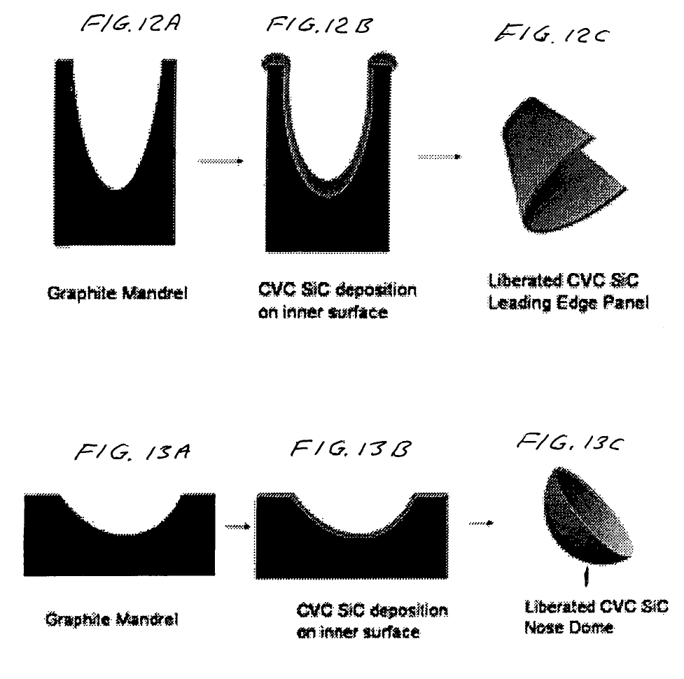

An important application of the present invention is the production of protective plates for reentry vehicles. Preferably these plates are SiC CVC structures produced using one of the techniques described above. FIGS. 12A-C show the principal steps in producing a leading edge plate and FIGS. 13A-C show the principal steps in producing a nose cone.

It is understood that the preceding description is given merely by way of illustration and not in limitation of the invention and that various modifications may be made thereto without departing from the spirit of the invention as claimed. For example, variations in the toughness and structure of composite articles formed by the method may be achieved by varying process parameters such as reactant gas stream flow and temperature, and the size, shape, and materials of the particles or fibers used as a second phase material. High temperature CVD techniques as well as plasma enhanced CVD (PECVD) techniques can be utilized along with the addition of particles using the techniques described above.

The scope of the invention is indicated by the appended claims, and all changes which come within the meaning and range of equivalency of the claims are intended to be embraced therein.

What is claimed is:

1. A method of forming a composite article comprising:
A) providing a reactor vessel having a removable bottom cover and a rotating table mounted on the bottom cover and a work zone at least as large as one cubic meter;
B) removing the bottom cover and providing a substrate on the rotating table and replacing the bottom cover so that the substrate is located on the rotating table within the work zone of the reactor vessel;
C) forming a mixture of particles of a solid phase material and a reactant gas, said reactant gas being thermally activatable to produce chemical vapor deposition (CVD) vapors and other reaction products;
D) thermally activating said reactant gas such that said gas reacts to produce said CVD vapors that deposit as solids on said substrate;
E) co-depositing with said CVD vapors said solid phase material onto said substrate to form composite material at a density within a predetermined density range and an average grain size within a predetermined grain size range, said composite material consisting essentially of (i) a solid matrix formed by chemical vapor deposition of said material from said reactant vapors and (ii) said solid phase material dispersed within said solid matrix;
F) maintaining said density within said predetermined density range and said average grain size within said predetermined grain size range by controlling the number of particles of solid phase material per flow rate of reactant gas within a predetermined particles per flow rate range and controlling said gas pressure within said reactor vessel within a predetermined gas pressure range; and
G) removing the substrate and the co-deposited composite material from the reactor vessel.

2. The method as in claim 1 wherein the reactor vessel comprises:
A) a stainless steel shell,
B) at least six electric resistance heating elements,
C) a water-cooled cooling jacket, and
D) an exhaust region located below the work zone for permitting reaction of un-reacted precursor gasses, and
has a work zone volume as large as or larger than about 3.37 cubic meters.

3. The method as in claim 2 wherein said reactor vessel is mounted on a frame and substrates are provided in the work zone by lowering the bottom cover and rolling the bottom cover on rails from under the work zone.

4. A method as in claim 1 wherein said thermal activation comprises heating said substrate and contacting said heated substrate with said mixture.

5. The method of claim 1 wherein said particles of solid phase material comprises fiber shaped particles.

6. The method of claim 3 wherein said particles of solid phase material comprises approximately shaped particles of a desired mesh size.

7. The method of claim 1 wherein the reactant gas comprises methyltrichlorosilane gas and hydrogen gas and the solid matrix is silicon carbide.

8. The method of claim 7 wherein the methyltrichlorosilane gas is produced in a vaporizer from liquid methyltrichlorosilane and hydrogen gas is produced in a hydrogen generator from water.

9. The method of claim 7 wherein the reactant gas is comprised of about 15 percent methyltrichlorosilane and 85 percent hydrogen.

10. The method of claim 9 wherein the solid phase material is silicon carbide particles.

11. The method of claim 9 wherein the solid phase material is silicon carbide fibers.

12. The method of claim 1 wherein the substrate is comprised of graphite.

13. The method of claim 1 wherein the matrix material, the reactant gas and the solid phase material consists one of the 33 combinations of matrix, chemical route and solid phase materials identified in the following table:
Chemical Vapor Composites Processes

| | | | Solid Particulate Phase Added |
|---|---|---|---|
| | | Chemical Route | (*principal additive for grain growth |
| No. | CVD Matrix | (*preferred) | renucleation). |
| 1 | Silicon | *CH₃SCl₃ → SiC + 3 | SiC*, Si₃N₄, ZrO₂, carbon fibers, |
| | Carbide | HCl | carbon nanotubes, SiC fibers, SiC |
| | SiC | | whiskers. Any compatible solid. |
| 2 | Silicon | *3SiCl₄ + 4NH₃ → | Si₃N₄*, SiC, ZrO₂, carbon fibers, |
| | Nitride | Si₃N₄ + 12 HCl | carbon nanotubes, SiC fibers, SiC |
| | Si₃N₄ | | whiskers. Any compatible solid. |
| 3 | Boron | *BCl₃ + NH₃ → BN + 3HCl | BN*, SiC, Si₃N₄, ZrO₂, carbon fibers, |
| | Nitride | | carbon nanotubes, SiC fibers, SiC |
| | BN | | whiskers. Any compatible solid. |
| 4 | Aluminum | *AlCl₃ + NH₃ → AlN + 3 | AlN*, BN, SiC, Si₃N₄, ZrO₂, carbon |
| | Nitride | HCl | fibers, carbon nanotubes, SiC fibers, SiC |
| | AlN | | whiskers. Any compatible solid. |
| 5 | Hafnium | *2 HfCl₄ + N₂ + 4H₂ → | HfN*, SiC, carbon fibers, carbon |
| | Nitride | 2HfN + 8 HCl | nanotubes, SiC fibers, SiC whiskers. Any |
| | HfN | | compatible solid. |
| 6 | Niobium | *2 NbCl₄ + N₂ + 4H₂ → | NbN*, HfN, SiC, carbon fibers, |
| | Nitride | 2NbN + 8 HCl | carbon nanotubes, SiC fibers, SiC |
| | NbN | | whiskers. Any compatible solid. |
| 7 | Zirconium | *ZrCl₄ + 2BCl₃ + 5H₂ → | ZrB₂*, HfB₂, ZrC, HfC, TaC, SiC, |
| | Diboride | ZrB₂ + 10 HCl | carbon fibers, carbon nanotubes, SiC |
| | ZrB₂ | | fibers, SiC whiskers. Any compatible |
| | | | solid. |
| 8 | Zirconium | 1. Zr + 2Cl₂ → ZrCl₄ | ZrB₂*, HfB₂, ZrC, HfC, TaC, SiC, |
| | Diboride | 2. ZrCl₄ + 2BCl₃ + 5H₂ | carbon fibers, carbon nanotubes, SiC |
| | ZrB₂ | → ZrB₂ + 10 HCl | fibers, SiC whiskers. Any compatible |
| | | | solid. |
| 9 | Zirconium | 1. Zr + 4HCl → ZrCl₄ + 2H₂ | ZrB₂*, HfB₂, ZrC, HfC, TaC, SiC, |
| | Diboride | 2. ZrCl₄ + 2BCl₃ + 5H₂ | carbon fibers, carbon nanotubes, SiC |
| | ZrB₂ | → ZrB₂ + 10 HCl | fibers, SiC whiskers. Any compatible |
| | | | solid. |
| 10 | Zirconium | Zr(BH₄)₂ → ZrB₂ + 4 | ZrB₂*, HfB₂, ZrC, HfC, TaC, SiC, Si₃N₄, |
| | Diboride | H₂ | ZrO₂, carbon fibers, |
| | ZrB₂ | | carbon nanotubes, SiC fibers, SiC |
| | | | whiskers. Any compatible solid. |
| 11 | Hafnium | *HfCl₄ + 2BCl₃ + 5H₂ | HfB₂*, ZrB₂, ZrC, HfC, TaC, SiC, |
| | Diboride | → HfB₂ + 10 HCl | carbon fibers, carbon nanotubes, SiC |
| | HfB₂ | | fibers, SiC whiskers. Any compatible |
| | | | solid. |
| 12 | Hafnium | 1. Hf + 2Cl₂ → HfCl₄ | HfB₂*, ZrB₂, ZrC, HfC, TaC, SiC, |
| | Diboride | 2. HfCl₄ + 2BCl₃ + 5H₂ | carbon fibers, carbon nanotubes, SiC |
| | HfB₂ | → HfB₂ + 10 HCl | fibers, SiC whiskers. Any compatible |
| | | | solid. |
| 13 | Hafnium | 1. Hf + 4HCl → HfCl₄ + 2H₂ | HfB₂,* ZrB₂, ZrC, HfC, TaC, SiC, Si₃N₄, |
| | Diboride | 2. HfCl₄ + 2BCl₃ + 5H₂ | ZrO₂, carbon fibers, carbon nanotubes, |
| | HfB₂ | → HfB₂ + 10 HCl | SiC fibers, SiC whiskers. Any |
| | | | compatible solid. |
| 14 | Tantalum | *TaX₄ + B₂H₆ → TaB₂ + 4 | TaB₂*, ZrB₂, HfB₂, ZrC, HfC, TaC, SiC, |
| | Diboride | HX + H₂ | Si₃N₄, ZrO₂, carbon fibers, carbon |
| | TaB₂ | X = Cl, Br. | nanotubes, SiC fibers, SiC whiskers. Any |
| | | | compatible solid. |
| 15 | Titanium | *TiCl₄ + 2BCl₃ + 5H₂ → | TiB₂*, ZrB₂, HfB₂, ZrC, HfC, TaC, SiC, |
| | Diboride | TiB₂ + 10 HCl | carbon fibers, carbon nanotubes, SiC |
| | HfB₂ | | fibers, SiC whiskers. Any compatible |
| | | | solid. |
| 16 | Boron | *4BCl₃ + CCl₄ + 8 H₂ | B₄C*, TiB₂, ZrB₂, HfB₂, ZrC, HfC, TaC, |
| | Carbide | → B₄C + 16 HCl | SiC, carbon fibers, carbon nanotubes, |
| | B₄C | | SiC fibers, SiC whiskers. Any |
| | | | compatible solid. |
| 17 | Boron | 4 BCl₃ + CH₄ + H₂ → | B₄C*, TiB₂, ZrB₂, HfB₂, ZrC, HfC, TaC, |
| | Carbide | B₄C + 12 HCl | SiC, carbon fibers, carbon nanotubes, |
| | B₄C | | SiC fibers, SiC whiskers. Any |
| | | | compatible solid. |
| 18 | Zirconium | *ZrCl₄ + CH₃Cl + H₂ → | ZrC*, ZrB₂, HfB₂, HfC, TaC, SiC, carbon |
| | Carbide | ZrC + 5 HCl | fibers, carbon nanotubes, SiC fibers, SiC |
| | ZrC | | whiskers. Any compatible solid. |
| 19 | Zirconium | 1. Zr + 2Cl₂ → ZrCl₄ | ZrC,* ZrB₂, HfB₂, HfC, TaC, SiC, |
| | Carbide | 2. ZrCl₄ + CH₃Cl + H₂ | carbon fibers, carbon nanotubes, SiC |
| | ZrC | → ZrC + 5 HCl | fibers, SiC whiskers. Any compatible |
| | | | solid. |
| 20 | Zirconium | 1. Zr + 4HCl → ZrCl₄ + 2H₂ | ZrC,* ZrB₂, HfB₂, HfC, TaC, SiC, |
| | Carbide | 2. ZrCl₄ + CH₃Cl + H₂ | carbon fibers, carbon nanotubes, SiC |
| | ZrC | → ZrC + 5 HCl | fibers, SiC whiskers. Any compatible |
| | | | solid. |
| 21 | Zirconium | ZrBr₄ + CH₄ → ZrC + 4 | ZrC,* ZrB₂, HfB₂, HfC, TaC, SiC, Si₃N₄, |
| | Carbide | HBr | ZrO₂, carbon fibers, carbon nanotubes, |
| | ZrC | | SiC fibers, SiC whiskers. Any |
| | | | compatible solid. |
| 22 | Hafnium | *HfCl₄ + CH₃Cl + H₂ → | HfC*, ZrB₂, HfB₂, ZrC, TaC, SiC, carbon |
| | Carbide | HfC + 5 HCl | fibers, carbon nanotubes, SiC fibers, SiC |
| | HfC | | whiskers. Any compatible solid. |
| 23 | Hafnium | 1. Hf + 2Cl₂ → HfCl₄ | HfC*, ZrB₂, HfB₂, ZrC, TaC, SiC, carbon |
| | Carbide | 2. HfCl₄ + CH₃Cl + H₂ | fibers, carbon nanotubes, SiC fibers, SiC |
| | HfC | → HfC + 5 HCl | whiskers. Any compatible solid. |
| 24 | Hafnium | 1. Hf + 4HCl → HfCl₄ + 2H₂ | HfC,* ZrB₂, HfB₂, ZrC, TaC, SiC, |
| | Carbide | 2. HfCl₄ + CH₃Cl + H₂ | carbon fibers, carbon nanotubes, SiC |
| | HfC | → HfC + 5 HCl | fibers, SiC whiskers. Any compatible |
| | | | solid. |
| 25 | Tantalum | *CH₄ + Ta → TaC + 2H₂ | TaC*, ZrB₂, HfB₂, ZrC, HfC, TaC, SiC, |
| | Carbide | Preferred for conversion | Si₃N₄, ZrO₂, carbon fibers, carbon |
| | TaC | of surface layer of | nanotubes, SiC fibers, SiC whiskers. Any |
| | | existing Ta solid phase. | compatible solid. |
| 26 | Tantalum | *1. Ta + 2 Cl₂ → TaCl₄ | TaC*, ZrB₂, HfB₂, ZrC, HfC, TaC, SiC, |
| | Carbide | 2. TaCl₄ + CH₃Cl + H₂ | carbon fibers, carbon nanotubes, SiC |
| | TaC | → TaC + 5 HCl | fibers, SiC whiskers. Any compatible |
| | | Preferred for thick TaC | solid. |
| | | deposits. | |
| 27 | Titanium | *TiCl₄ + CH₄ → TiC + 4 | TiC*, ZrB₂, HfB₂, ZrC, HfC, TaC, SiC, |
| | Carbide | HCl | Si₃N₄, ZrO₂, carbon fibers, carbon |
| | TiC | | nanotubes, SiC fibers, SiC whiskers. Any |
| | | | compatible solid. |
| 28 | Tungsten | *WCl₆ + CH₄ + H₂ → | WC*, ZrB₂, HfB₂, ZrC, HfC, TaC, SiC, |
| | Carbide | WC + 6 HCl | carbon fibers, carbon nanotubes, SiC |
| | WC | | fibers, SiC whiskers. Any compatible |
| | | | solid. |
| 29 | Tungsten | WF₆ + CH₃OH + 2H₂ | WC*, ZrB₂, HfB₂, ZrC, HfC, TaC, SiC, |
| | Carbide | → WC + 6 HF + H₂O | carbon fibers, carbon nanotubes, SiC |
| | WC | | fibers, SiC whiskers. Any compatible |
| | | | solid. |
| 30 | Chromium | *7 CrCl₄ + C₃H₈ + 10 | Cr₇C₃*, WC, ZrB₂, HfB₂, ZrC, HfC, |
| | Carbide | H₂ → Cr₇C₃ + 28 HCl | TaC, SiC, carbon fibers, carbon |
| | Cr₇C₃ | | nanotubes, SiC fibers, SiC whiskers. Any |
| | | | compatible solid. |
| 31 | Tungsten W | *WCl₆ + 3 H₂ → W + 6 | W*, ZrB₂, HfB₂, ZrC, HfC, TaC, SiC, |
| | | HCl | carbon fibers, carbon nanotubes, SiC |
| | | | fibers, SiC whiskers. Any compatible |
| | | | solid. |
| 32 | Tungsten W | W(CO)₆ → W + CO | W*, ZrB₂, HfB₂, ZrC, HfC, TaC, SiC, |
| | | | Si₃N₄, ZrO₂, carbon fibers, |
| | | | carbon nanotubes, SiC fibers, SiC |
| | | | whiskers. Any compatible solid. |
| 33 | Diamond C | CH₄ → C + 2 H₂ | C (diamond)*, SiC, any compatible solid |

14. The method as in claim 1 wherein the solid phase material is in the form of nanoparticles.

15. The method as in claim 14 wherein said nanoparticles are nanotubes.

16. The method as in claim 1 wherein a plurality of additional substrates are provided on said rotating table and composite material is co-deposited on each of the substrates.

17. The method as in claim 16 wherein each of the substrates are vertical slats.

18. The method as in claim 1 wherein the substrate has a shape corresponding to the inverse shape of a mirror and the co-deposited material has the shape of the mirror.

19. The method as in claim 18 wherein the mirror is a concave mirror.

20. The method as in claim 1 wherein the composite material comprises a metal boride matrix material produced via:
MCl_{4(g)}+2BCl_{3(g)}+5H_{2(g)}→MB_{2(S)}+10 HCl_{(g)}
where M=Hf, Zr, Ta, or Ti, BCl₃ is boron trichloride, and H₂ is hydrogen gas.

21. The method as in claim 1 wherein the composite material comprises a carbide matrix material produced via:
MCl_{4(g)}+CH₃Cl_{(g)}+H_{2(g}→MC₍ₛ₎+5HCl_{(g)}
where M=Hf, Zr, to Ta, CH₃Cl is chloromethane, and H₂ is hydrogen gas.

22. The method as in claim 1 wherein the composite material comprises a nitride matrix material produced via:
MCl_{4(g)}+N_{2(g)}+4H_{2(g)}→2MN₍ₛ₎+8HCl_{(g)}
where M=Hf, Zr, to Ta, and N₂ and H₂ are nitrogen and hydrogen gas, respectively.

23. The method as in claim 1 wherein the co-deposited composite material is deposited as thin films by changing the size and/or number of particles of solid phase material.

24. The method as in claim 1 wherein the co-deposited composite material is deposited as thin films by changing the gas chemical or physical properties.

25. The method as in claim 1 wherein the co-deposited material is deposited to produce thin films comprising Bragg stack optics.

26. The method as in claim 1 wherein the co-deposited material is deposited to produce heater elements.

27. The method as in claim 1 wherein the co-deposited material is produced at pressures much lower than atmospheric.

28. The method as in claim 27 wherein the co-deposited material is translucent and is utilized for its transparent properties.

29. A method of forming a composite article comprising:
A) providing a reactor vessel having a work zone of at least as large as 1 cubic meter and rotating means for rotating within the reactor vessel, around an approximately horizontal axis, a substrate;
B) forming a mixture of particles of a solid phase material and a reactant gas, said reactant gas being thermally activatable to produce chemical vapor deposition (CVD) vapors and other reaction products;
D) thermally activating said reactant gas such that said gas reacts to produce said CVD vapors that deposit as solids onto said substrate;
E) co-depositing with said CVD vapors said solid phase material onto said substrate to form composite material at a density within a predetermined density range and an average grain size within a predetermined grain size range, said composite material consisting essentially of (i) a solid matrix formed by chemical vapor deposition of said material from said CVD vapors and (ii) said solid phase material dispersed within said solid matrix;
F) maintaining said density within said predetermined density range and said average grain size within said predetermined grain size range by controlling the number of particles of solid phase material per flow rate of reactant gas within a predetermined particles per flow rate range and controlling said gas pressure within said reactor vessel within a predetermined gas pressure range; and
G) removing the substrate and the co-deposited composite material from the reactor vessel.

30. A method as in claim 29 wherein said thermal activation comprises heating said substrate and contacting said heated substrate with said mixture.

31. The method of claim 2 wherein said particles of solid phase material comprises fiber shaped particles.

32. The method of claim 31 wherein said particles of solid phase material comprises approximately shaped particles of a desired mesh size.

33. The method of claim 29 wherein the reactant gas comprises methyltrichlorosilane gas and hydrogen gas and the solid matrix is silicon carbide.

34. The method of claim 33 wherein the methyltrichlorosilane gas is produced in a vaporizer from liquid methyltrichlorosilane and hydrogen gas is produced in a hydrogen generator from wate.

35. The method of claim 33 wherein the reactant gas is comprised of about 15 percent methyltrichlorosilane and 85 percent hydrogen.

36. The method of claim 35 wherein the solid phase material is silicon carbide particles.

37. The method of claim 35 wherein the solid phase material is silicon carbide fibers.

38. The method of claim 29 wherein the substrate is comprised of graphite.

39. The method of claim 29 wherein the matrix material, the reactant gas and the solid phase material consists one of the 33 combinations of matrix, chemical route and solid phase materials identified in the following table:
Chemical Vapor Composites Processes

| | | | Solid Particulate Phase Added |
|---|---|---|---|
| | | Chemical Route | (*principal additive for grain growth |
| No. | CVD Matrix | (*preferred) | renucleation). |
| 1 | Silicon | *CH₃SCl₃ → SiC + 3 | SiC*, Si₃N₄, ZrO₂, carbon fibers, |
| | Carbide | HCl | carbon nanotubes, SiC fibers, SiC |
| | SiC | | whiskers. Any compatible solid. |
| 2 | Silicon | *3SiCl₄ + 4NH₃ → | Si₃N₄*, SiC, ZrO₂, carbon fibers, |
| | Nitride | Si₃N₄ + 12 HCl | carbon nanotubes, SiC fibers, SiC |
| | Si₃N₄ | | whiskers. Any compatible solid. |
| 3 | Boron | *BCl₃ + NH₃ → BN + 3HCl | BN*, SiC, Si₃N₄, ZrO₂, carbon fibers, |
| | Nitride | | carbon nanotubes, SiC fibers, SiC |
| | BN | | whiskers. Any compatible solid. |
| 4 | Aluminum | *AlCl₃ + NH₃ → AlN + 3 | AlN*, BN, SiC, Si₃N₄, ZrO₂, carbon |
| | Nitride | HCl | fibers, carbon nanotubes, SiC fibers, SiC |
| | AlN | | whiskers. Any compatible solid. |
| 5 | Hafnium | *2 HfCl₄ + N₂ + 4H₂ → | HfN*, SiC, carbon fibers, carbon |
| | Nitride | 2HfN + 8 HCl | nanotubes, SiC fibers, SiC whiskers. Any |
| | HfN | | compatible solid. |
| 6 | Niobium | *2 NbCl₄ + N₂ + 4H₂ → | NbN*, HfN, SiC, carbon fibers, |
| | Nitride | 2NbN + 8 HCl | carbon nanotubes, SiC fibers, SiC |
| | NbN | | whiskers. Any compatible solid. |
| 7 | Zirconium | *ZrCl₄ + 2BCl₃ + 5H₂ → | ZrB₂*, HfB₂, ZrC, HfC, TaC, SiC, |
| | Diboride | ZrB₂ + 10 HCl | carbon fibers, carbon nanotubes, SiC |
| | ZrB₂ | | fibers, SiC whiskers. Any compatible |
| | | | solid. |
| 8 | Zirconium | 1. Zr + 2Cl₂ → ZrCl₄ | ZrB₂*, HfB₂, ZrC, HfC, TaC, SiC, |
| | Diboride | 2. ZrCl₄ + 2BCl₃ + 5H₂ | carbon fibers, carbon nanotubes, SiC |
| | ZrB₂ | → ZrB₂ + 10 HCl | fibers, SiC whiskers. Any compatible |
| | | | solid. |
| 9 | Zirconium | 1. Zr + 4HCl → ZrCl₄ + 2H₂ | ZrB₂*, HfB₂, ZrC, HfC, TaC, SiC, |
| | Diboride | 2. ZrCl₄ + 2BCl₃ + 5H₂ | carbon fibers, carbon nanotubes, SiC |
| | ZrB₂ | → ZrB₂ + 10 HCl | fibers, SiC whiskers. Any compatible |
| | | | solid. |
| 10 | Zirconium | Zr(BH₄)₂ → ZrB₂ + 4 | ZrB₂*, HfB₂, ZrC, HfC, TaC, SiC, Si₃N₄, |
| | Diboride | H₂ | ZrO₂, carbon fibers, |
| | ZrB₂ | | carbon nanotubes, SiC fibers, SiC |
| | | | whiskers. Any compatible solid. |
| 11 | Hafnium | *HfCl₄ + 2BCl₃ + 5H₂ | HfB₂*, ZrB₂, ZrC, HfC, TaC, SiC, |
| | Diboride | → HfB₂ + 10 HCl | carbon fibers, carbon nanotubes, SiC |
| | HfB₂ | | fibers, SiC whiskers. Any compatible |
| | | | solid. |
| 12 | Hafnium | 1. Hf + 2Cl₂ → HfCl₄ | HfB₂*, ZrB₂, ZrC, HfC, TaC, SiC, |
| | Diboride | 2. HfCl₄ + 2BCl₃ + 5H₂ | carbon fibers, carbon nanotubes, SiC |
| | HfB₂ | → HfB₂ + 10 HCl | fibers, SiC whiskers. Any compatible |
| | | | solid. |
| 13 | Hafnium | 1. Hf + 4HCl → HfCl₄ + 2H₂ | HfB₂,* ZrB₂, ZrC, HfC, TaC, SiC, Si₃N₄, |
| | Diboride | 2. HfCl₄ + 2BCl₃ + 5H₂ | ZrO₂, carbon fibers, carbon nanotubes, |
| | HfB₂ | → HfB₂ + 10 HCl | SiC fibers, SiC whiskers. Any |
| | | | compatible solid. |
| 14 | Tantalum | *TaX₄ + B₂H₆ → TaB₂ + 4 | TaB₂*, ZrB₂, HfB₂, ZrC, HfC, TaC, SiC, |
| | Diboride | HX + H₂ | Si₃N₄, ZrO₂, carbon fibers, carbon |
| | TaB₂ | X = Cl, Br. | nanotubes, SiC fibers, SiC whiskers. Any |
| | | | compatible solid. |
| 15 | Titanium | *TiCl₄ + 2BCl₃ + 5H₂ → | TiB₂*, ZrB₂, HfB₂, ZrC, HfC, TaC, SiC, |
| | Diboride | TiB₂ + 10 HCl | carbon fibers, carbon nanotubes, SiC |
| | HfB₂ | | fibers, SiC whiskers. Any compatible |
| | | | solid. |
| 16 | Boron | *4BCl₃ + CCl₄ + 8 H₂ | B₄C*, TiB₂, ZrB₂, HfB₂, ZrC, HfC, TaC, |
| | Carbide | → B₄C + 16 HCl | SiC, carbon fibers, carbon nanotubes, |
| | B₄C | | SiC fibers, SiC whiskers. Any |
| | | | compatible solid. |
| 17 | Boron | 4 BCl₃ + CH₄ + H₂ → | B₄C*, TiB₂, ZrB₂, HfB₂, ZrC, HfC, TaC, |
| | Carbide | B₄C + 12 HCl | SiC, carbon fibers, carbon nanotubes, |
| | B₄C | | SiC fibers, SiC whiskers. Any |
| | | | compatible solid. |
| 18 | Zirconium | *ZrCl₄ + CH₃Cl + H₂ → | ZrC*, ZrB₂, HfB₂, HfC, TaC, SiC, carbon |
| | Carbide | ZrC + 5 HCl | fibers, carbon nanotubes, SiC fibers, SiC |
| | ZrC | | whiskers. Any compatible solid. |
| 19 | Zirconium | 1. Zr + 2Cl₂ → ZrCl₄ | ZrC,* ZrB₂, HfB₂, HfC, TaC, SiC, |
| | Carbide | 2. ZrCl₄ + CH₃Cl + H₂ | carbon fibers, carbon nanotubes, SiC |
| | ZrC | → ZrC + 5 HCl | fibers, SiC whiskers. Any compatible |
| | | | solid. |
| 20 | Zirconium | 1. Zr + 4HCl → ZrCl₄ + 2H₂ | ZrC,* ZrB₂, HfB₂, HfC, TaC, SiC, |
| | Carbide | 2. ZrCl₄ + CH₃Cl + H₂ | carbon fibers, carbon nanotubes, SiC |
| | ZrC | → ZrC + 5 HCl | fibers, SiC whiskers. Any compatible |
| | | | solid. |
| 21 | Zirconium | ZrBr₄ + CH₄ → ZrC + 4 | ZrC,* ZrB₂, HfB₂, HfC, TaC, SiC, Si₃N₄, |
| | Carbide | HBr | ZrO₂, carbon fibers, carbon nanotubes, |
| | ZrC | | SiC fibers, SiC whiskers. Any |
| | | | compatible solid. |
| 22 | Hafnium | *HfCl₄ + CH₃Cl + H₂ → | HfC*, ZrB₂, HfB₂, ZrC, TaC, SiC, carbon |
| | Carbide | HfC + 5 HCl | fibers, carbon nanotubes, SiC fibers, SiC |
| | HfC | | whiskers. Any compatible solid. |
| 23 | Hafnium | 1. Hf + 2Cl₂ → HfCl₄ | HfC*, ZrB₂, HfB₂, ZrC, TaC, SiC, carbon |
| | Carbide | 2. HfCl₄ + CH₃Cl + H₂ | fibers, carbon nanotubes, SiC fibers, SiC |
| | HfC | → HfC + 5 HCl | whiskers. Any compatible solid. |
| 24 | Hafnium | 1. Hf + 4HCl → HfCl₄ + 2H₂ | HfC,* ZrB₂, HfB₂, ZrC, TaC, SiC, |
| | Carbide | 2. HfCl₄ + CH₃Cl + H₂ | carbon fibers, carbon nanotubes, SiC |
| | HfC | → HfC + 5 HCl | fibers, SiC whiskers. Any compatible |
| | | | solid. |
| 25 | Tantalum | *CH₄ + Ta → TaC + 2H₂ | TaC*, ZrB₂, HfB₂, ZrC, HfC, TaC, SiC, |
| | Carbide | Preferred for conversion | Si₃N₄, ZrO₂, carbon fibers, carbon |
| | TaC | of surface layer of | nanotubes, SiC fibers, SiC whiskers. Any |
| | | existing Ta solid phase. | compatible solid. |
| 26 | Tantalum | *1. Ta + 2 Cl₂ → TaCl₄ | TaC*, ZrB₂, HfB₂, ZrC, HfC, TaC, SiC, |
| | Carbide | 2. TaCl₄ + CH₃Cl + H₂ | carbon fibers, carbon nanotubes, SiC |
| | TaC | → TaC + 5 HCl | fibers, SiC whiskers. Any compatible |
| | | Preferred for thick TaC | solid. |
| | | deposits. | |
| 27 | Titanium | *TiCl₄ + CH₄ → TiC + 4 | TiC*, ZrB₂, HfB₂, ZrC, HfC, TaC, SiC, |
| | Carbide | HCl | Si₃N₄, ZrO₂, carbon fibers, carbon |
| | TiC | | nanotubes, SiC fibers, SiC whiskers. Any |
| | | | compatible solid. |
| 28 | Tungsten | *WCl₆ + CH₄ + H₂ → | WC*, ZrB₂, HfB₂, ZrC, HfC, TaC, SiC, |
| | Carbide | WC + 6 HCl | carbon fibers, carbon nanotubes, SiC |
| | WC | | fibers, SiC whiskers. Any compatible |
| | | | solid. |
| 29 | Tungsten | WF₆ + CH₃OH + 2H₂ | WC*, ZrB₂, HfB₂, ZrC, HfC, TaC, SiC, |
| | Carbide | → WC + 6 HF + H₂O | carbon fibers, carbon nanotubes, SiC |
| | WC | | fibers, SiC whiskers. Any compatible |
| | | | solid. |
| 30 | Chromium | *7 CrCl₄ + C₃H₈ + 10 | Cr₇C₃*, WC, ZrB₂, HfB₂, ZrC, HfC, |
| | Carbide | H₂ → Cr₇C₃ + 28 HCl | TaC, SiC, carbon fibers, carbon |
| | Cr₇C₃ | | nanotubes, SiC fibers, SiC whiskers. Any |
| | | | compatible solid. |
| 31 | Tungsten W | *WCl₆ + 3 H₂ → W + 6 | W*, ZrB₂, HfB₂, ZrC, HfC, TaC, SiC, |
| | | HCl | carbon fibers, carbon nanotubes, SiC |
| | | | fibers, SiC whiskers. Any compatible |
| | | | solid. |
| 32 | Tungsten W | W(CO)₆ → W + CO | W*, ZrB₂, HfB₂, ZrC, HfC, TaC, SiC, |
| | | | Si₃N₄, ZrO₂, carbon fibers, |
| | | | carbon nanotubes, SiC fibers, SiC |
| | | | whiskers. Any compatible solid. |
| 33 | Diamond C | CH₄ → C + 2 H₂ | C (diamond)*, SiC, any compatible solid |

40. The method as in claim 29 wherein the solid phase material is in the form of nanoparticles.

41. The method as in claim 40 wherein said nanoparticles are nanotubes.
